(19) United States
(12) Patent Application Publication
(10) Pub. No.: US 2026/0267221 A1
(43) Pub. Date: Sep. 10, 2026

(54) METHOD OF MANUFACTURING SEMICONDUCTOR DEVICE

(71) Applicant: Samsung Electronics Co., Ltd., Suwon-si (KR)

(72) Inventors: Hyeokjin Kim, Suwon-si (KR); Jaeseong Park, Suwon-si (KR); Junsuk Lee, Suwon-si (KR); Kwangmin Choi, Suwon-si (KR); Chunhwa Jung, Suwon-si (KR)

(21) Appl. No.: 19/555,103

(22) Filed: Mar. 3, 2026

(30) Foreign Application Priority Data
Mar. 6, 2025 (KR) 10-2025-0029200

(51) Int. Cl. G03F 1/76; G03F 7/00; H10P 76/00; H10P 50/00

(52) U.S. Cl. CPC G03F 1/76; G03F 7/0035; H10P 76/00; H10P 50/69; H10P 50/71; H10P 50/73

(57) ABSTRACT

A method of manufacturing a semiconductor device includes forming a mask layer on a pattern target layer, exposing and developing the mask layer by using a multi-tone reticle including a white region and a gray region to form a first mask pattern region having a first thickness that exposes the pattern target layer and a second preliminary mask pattern region having a second sub-thickness that is less than the first thickness without exposing the pattern target layer, etching the pattern target layer located below the first mask pattern region and the mask layer and the pattern target layer remaining below the second preliminary mask pattern region to form a first pattern having a first depth and a second pattern having a second depth that is less than the first depth, and removing the mask layer.

### CROSS-REFERENCE TO RELATED APPLICATION

This application is based on and claims priority under 35 USC §119 to Korean Patent Application No. 10-2025-0029200, filed on March 6, 2025, in the Korean Intellectual Property Office, the disclosure of which is incorporated by reference herein in its entirety.

### BACKGROUND

The present disclosure relates to a method of manufacturing a semiconductor device, and more particularly, to a method of manufacturing a semiconductor device including a pattern formation process.

Manufacturing a semiconductor device may include a pattern formation process of forming a pattern on a semiconductor substrate (or wafer) a plurality of times. An increase in the number of pattern formation processes during the manufacturing of semiconductor devices may decrease the productivity, the reliability, and electrical performance of semiconductor devices.

### SUMMARY

Aspects of the inventive concept provide a method of manufacturing a semiconductor device, capable of reducing the number of pattern formation processes.

According to an aspect of the inventive concept, a method of manufacturing a semiconductor device includes forming a mask layer on a pattern target layer, exposing and developing the mask layer by using a multi-tone reticle including a white region and a gray region to form a first mask pattern region having a first thickness that exposes the pattern target layer and a second preliminary mask pattern region having a second sub-thickness that is less than the first thickness without exposing the pattern target layer, etching the pattern target layer located below the first mask pattern region and the mask layer and the pattern target layer remaining below the second preliminary mask pattern region to form a first pattern in the pattern target layer having a first depth and a second pattern in the pattern target layer having a second depth that is less than the first depth, and removing the mask layer.

According to another aspect of the inventive concept, a method of manufacturing a semiconductor device includes forming a mask layer on a pattern target layer, exposing and developing the mask layer by using a multi-tone reticle including a white region and first to third gray regions to form a first mask pattern region having a first thickness that exposes the pattern target layer and second to fourth preliminary mask pattern regions respectively having second to fourth sub-thicknesses that are sequentially less than the first thickness, without exposing the pattern target layer, etching the pattern target layer located below the first mask pattern region while etching the mask layer and the pattern target layer located below the second to fourth preliminary mask pattern regions to form first to fourth patterns respectively having first depth to fourth depth that are sequentially smaller, and removing the mask layer.

According to another aspect of the inventive concept, a method of manufacturing a semiconductor device includes forming high-density mask patterns and low-density mask patterns separate from each other on a semiconductor substrate, wherein the semiconductor substrate is a pattern target layer, the high-density mask patterns are apart from each other, and the low-density mask patterns are apart from each other, forming a mask layer on the high-density mask patterns and the low-density mask patterns, exposing and developing the mask layer by using a multi-tone reticle including a white region and a gray region to form a first mask exposure pattern region exposing the semiconductor substrate and the low-density mask patterns and a second mask pattern region not exposing the semiconductor substrate or the high-density mask patterns, etching the semiconductor substrate located below the first mask exposure pattern region to form first preliminary patterns and further etching the second mask pattern region to form a second mask exposure pattern region exposing the high-density mask patterns and the semiconductor substrate, and further etching the semiconductor substrate located below the first mask exposure pattern region and the first preliminary patterns to form first patterns having a first depth and etching the semiconductor substrate located below the high-density mask patterns of the second mask exposure pattern region to form second patterns having a second depth that is less than the first depth, wherein the first patterns are first trench patterns, the second patterns are second trench patterns, low-density active patterns are formed between the first trench patterns, and high-density active patterns are formed between the second trench patterns.

### BRIEF DESCRIPTION OF THE DRAWINGS

Embodiments will be more clearly understood from the following detailed description taken in conjunction with the accompanying drawings in which:

FIGS. 1A to 1E are cross-sectional views illustrating a method of manufacturing a semiconductor device, according to an embodiment;

FIG. 2 is a plan view illustrating a multi-tone reticle used in an exposure process of FIG. 1B;

FIGS. 3A to 3F are cross-sectional views illustrating a method of manufacturing a semiconductor device, according to an embodiment;

FIG. 4 is a plan view illustrating the multi-tone reticle used in the exposure process of FIG. 3A;

FIG. 5A is a perspective view illustrating mask pattern regions formed on a pattern target layer, according to an embodiment;

FIG. 5B is a perspective view illustrating patterns formed according to an embodiment;

FIG. 6 is a plan view illustrating a semiconductor device that may be manufactured according to an embodiment;

FIG. 7 is a schematic layout diagram illustrating main components of a cell region of a semiconductor device that may be manufactured according to an embodiment;

FIG. 8A is a cross-sectional view illustrating a semiconductor device that may be manufactured according to an embodiment;

FIG. 8B is an enlarged view of a portion of FIG. 8A;

FIG. 9A is a cross-sectional view illustrating a semiconductor device that may be manufactured according to an embodiment;

FIG. 9B is an enlarged view of a portion of FIG. 9A;

FIGS. 10A to 10G are cross-sectional views illustrating a method of manufacturing a semiconductor device, according to an embodiment;

FIGS. 11A, 11B, and 12 to 18 are cross-sectional views illustrating a method of manufacturing a semiconductor device illustrated in FIGS. 8A and 9A; and

FIG. 19 is a cross-sectional view illustrating a cell region and a peripheral circuit region of a semiconductor device manufactured according to an embodiment.

### DETAILED DESCRIPTION OF THE EMBODIMENTS

Hereinafter, embodiments of the inventive concept are described in detail with reference to the accompanying drawings. The embodiments of the inventive concept may be realized by a single embodiment described in connection with the various figures, and may also be realized by a combination of more than one embodiment described in more than one of the examples depicted in the various figures. Therefore, the technical idea of the inventive concept should not be construed by one of the described embodiments.

Herein, the singular form of components may include the plural form unless the context clearly indicates otherwise. Herein, the drawings are exaggerated to more clearly describe the inventive concept.

Herein, the terms "first," "second," etc., are used to describe various elements or components, but it is to be understood that these elements or components are not limited by these terms. These terms are only used to distinguish one element or component from another. Therefore, a first element or first component mentioned below may also be described as a second element or second component within the technical concept of the inventive concept. The terms “first,” “second,” etc., may be used purely as a naming convention, and so a claim may describe a “second” item for naming purposes even if a “first” of the same-named item is not listed in the claim.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

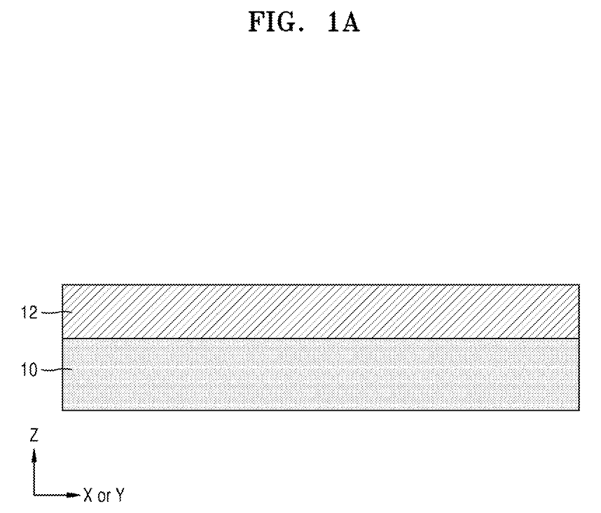

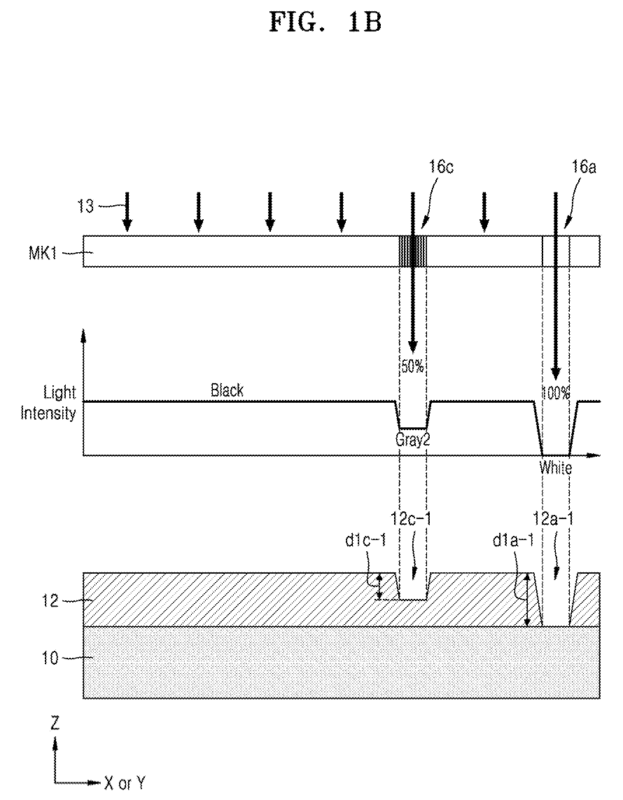

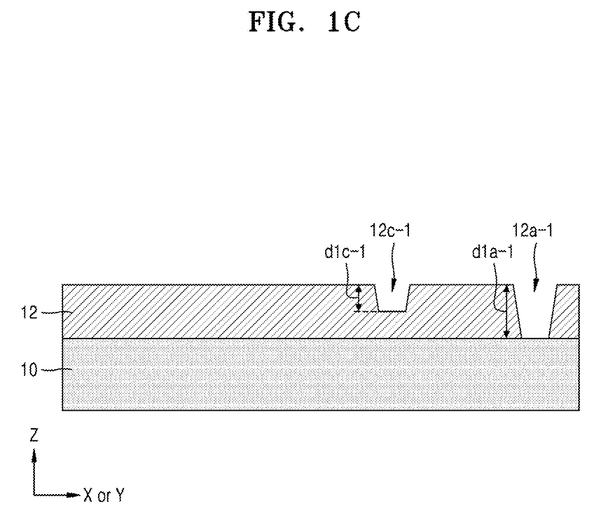

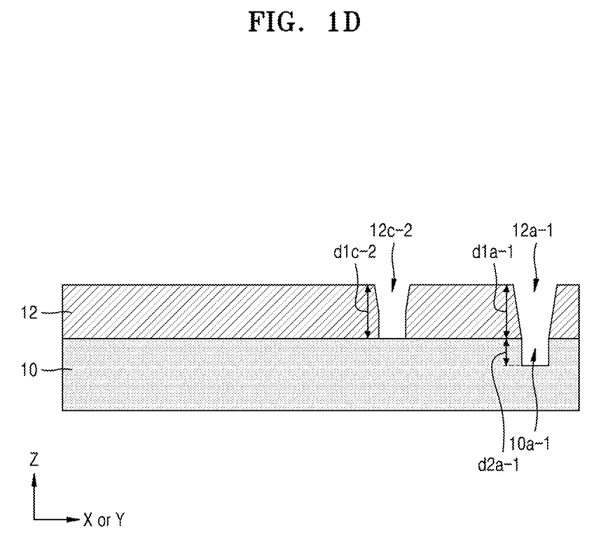

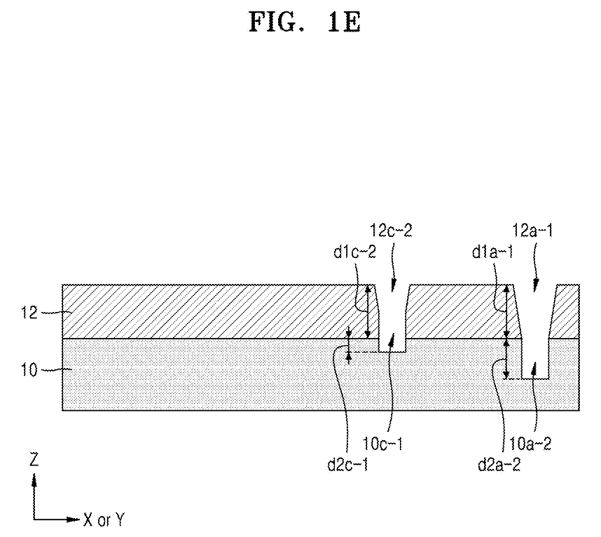

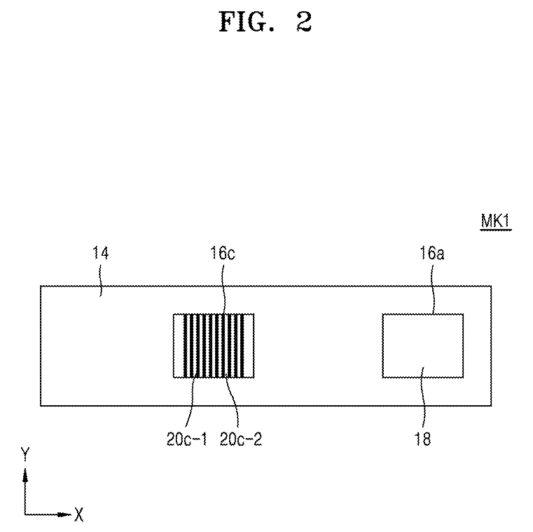

FIGS. 1A to 1E are cross-sectional views illustrating a method of manufacturing a semiconductor device, according to an embodiment, and FIG. 2 is a plan view illustrating a multi-tone reticle used in an exposure process of FIG. 1B.

The first, second, etc., steps described below include sequential meanings, but the inventive concept is not limited thereto. In FIGS. 1A to 1E, the X direction and the Y direction refer to a first horizontal direction and a second horizontal direction, respectively, which may be perpendicular to each other, and the Z direction may be a direction perpendicular to a plane defined by the X direction and the Y direction.

As shown in FIG. 1A, a mask layer 12 is formed on a pattern target layer 10. In some embodiments, the pattern target layer 10 may be a semiconductor substrate. In some embodiments, the pattern target layer 10 may be an insulating layer or a conductive layer used in the manufacture of a semiconductor device. In FIGS. 1A to 1E, the thickness of the mask layer 12 is not changed for convenience of explanation.

The mask layer 12 may be a photoresist layer that reacts to a 248-nm wavelength, a 193-nm wavelength, a 157-nm wavelength, an extreme ultraviolet wavelength, or a combination of these wavelengths. The mask layer 12 may be a chemical amplification-type photoresist layer. The mask layer 12 may be a positive photoresist layer or a negative photoresist layer.

As shown in FIGS. 1B, 1C, and 2, the mask layer 12 is exposed and developed using a multi-tone reticle MK1 including a white region (White) 16a and a gray region 16c. The mask layer 12 may be exposed by light 13 of a lithography device. The multi-tone reticle MK1 may include a halftone reticle. The halftone reticle may be considered as the opposite concept of a binary reticle.

The multi-tone reticle MK1 may include the white region 16a and the gray region 16c located on a mask substrate 14. The mask substrate 14 may be a black region through which light (13 in FIG. 1B) does not pass. The white region 16a may be a region in which light (13 in FIG. 1B) passes through the multi-tone reticle MK1. Though the reticle is in this example has only two types of openings with two different amounts of light transmittance, as discussed in the various embodiments below, different amounts of light can pass through multiple different types of openings in the multi-tone reticle. The openings may include fully open openings (e.g., open window), and partially blocked openings (e.g., filtered window). Therefore, a multi-tone reticle can have two or more different light transmittance windows (e.g., a fully open window and one or more differently-filtered windows).

The white region 16a may include a light-transmitting pattern 18. The gray region 16c may be a region in which a portion of the light (13 in FIG. 1B) passes through the multi-tone reticle MK1. The gray region 16c may include a plurality of slit line patterns 20c-1 and space patterns 20c-2 positioned between the slit line patterns 20c-1.

The white region 16a may be a region with a large amount of light transmittance that exposes the mask layer 12. The gray region 16c may be a region with a smaller amount of light transmittance than that of the white region 16a that exposes the mask layer 12. In some embodiments, the amount of light transmittance of the white region 16a may be 100%, and the amount of light transmittance of the gray region 16c may be 50%. However, the gray region may provide for other amounts of light transmittance, for example between 25% and 75% or other amounts less than 100% and greater than 0%.

As shown in the light intensity graph of FIG. 1B, when exposing the mask layer 12 by the light 13 of a lithography device, a portion of the multi-tone reticle MK1 through which the light 13 does not pass is indicated in black (Black), a portion of the multi-tone reticle MK1 through which the light 13 passes is indicated in white (White), and a portion of the multi-tone reticle MK1 through which a portion of the light 13 passes is indicated in gray Gray2. The light intensity may be greater for white than for gray Gray2.

After the mask layer 12 is exposed to the light 13 of a lithography device, when a development process is performed, a first mask pattern region 12a-1 and a second preliminary mask pattern region 12c-1 may be formed as shown in FIGS. 1B and 1C. The first mask pattern region 12a-1 may be formed to correspond to the white region 16a of the multi-tone reticle MK1.

The first mask pattern region 12a-1 exposes the pattern target layer 10 and may have a first thicknessd1a-1. The second preliminary mask pattern region 12c-1 may have a second sub-thickness d1c-1 that is less than the first thickness d1a-1, without exposing the pattern target layer 10.

As shown in FIGS. 1D and 1E, a first pattern 10a-2 and a second pattern 10c-1 are formed in the pattern target layer 10. For example, in one embodiment, the pattern target layer 10 located below the first mask pattern region 12a-1, and the mask layer 12 and the pattern target layer 10 remaining below the second preliminary mask pattern region (12c-1 of FIG. 1C) are etched to form a first pattern 10a-2 having a first depth d2a-2 and a second pattern 10c-1 having a second depth d2c-1 that is less than the first depthd2a-2.

The formation process of the first pattern 10a-2 and the second pattern 10c-1 is described in more detail as follows. As illustrated in FIG. 1D, the pattern target layer 10 located below the first mask pattern region 12a-1 is etched to form a first preliminary pattern 10a-1 having a first sub-depth d2a-1.

In addition, the mask layer 12 remaining below the second preliminary mask pattern region (12c-1 in FIG. 1C) is further etched to form a second mask pattern region 12c-2 having a second thickness d1c-2 that exposes the pattern target layer 10. The second thickness d1c-2 may be the same as to the first thickness d1a-1. The second preliminary mask pattern region (12c-1 in FIG. 1C) and the second mask pattern region 12c-2 may be formed to correspond to the gray region 16c of the multi-tone reticle MK1.

Subsequently, as illustrated in FIG. 1E, the pattern target layer 10 located below the first mask pattern region 12a-1 and the first preliminary pattern (10a-1 of FIG. 1D) is further etched to form the first pattern 10a-2 having the first depth d2a-2. The first depth d2a-2 may be deeper than the first sub-depth (d2a-1 in FIG. 1D).

In addition, the pattern target layer 10 located below the second mask pattern region 12c-2 is etched to form a second pattern 10c-1 having a second depth d2c-1 that is less than the first depth d2a-2. The first pattern 10a-2 and the second pattern 10c-1 may be trench patterns. When the pattern target layer 10 is a semiconductor substrate, the first pattern 10a-2 and the second pattern 10c-1 may be trench patterns formed within the semiconductor substrate.

Subsequently, by removing the mask layer 12, the method of manufacturing a layer in a semiconductor device including the first pattern 10a-2 and the second pattern 10c-1 may be completed. The method of manufacturing a semiconductor device according to this embodiment may improve the reliability and electrical performance of the semiconductor device by forming two patterns with different depths through a single exposure and development process and using a single reticle. For example, though FIGS. 1A-1E show different stages, the progression from the stage shown in FIG. 1A to the stage shown in FIG. 1E may be implemented using a single exposure and development process without the need for breaks within the exposure and development portion of the process and without the need for inserting additional mask layers or reticles. Therefore, multiple trenches of different depths can be formed in a single pattern-forming process simultaneously.

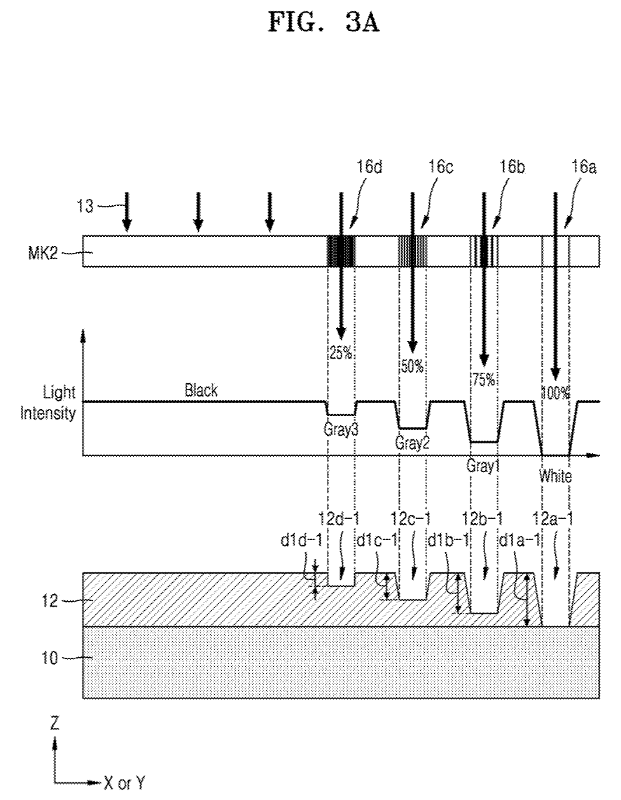

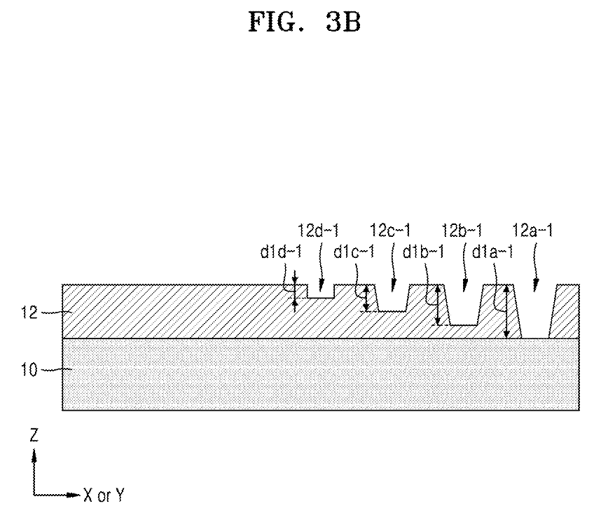

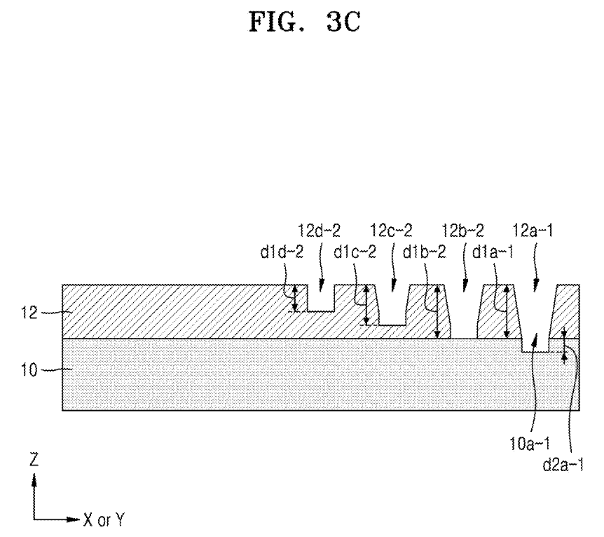

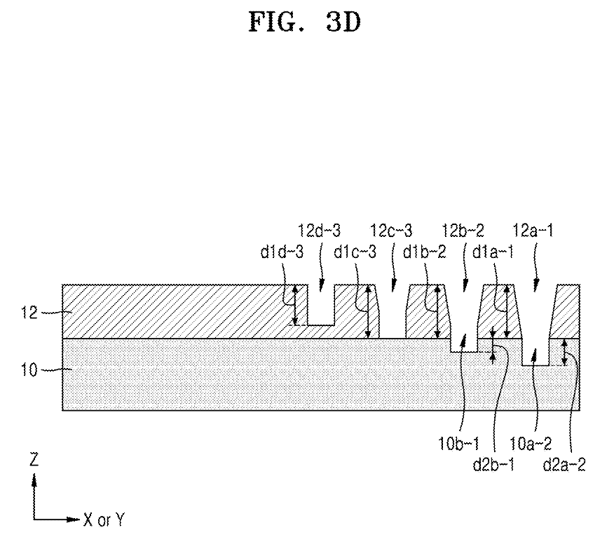

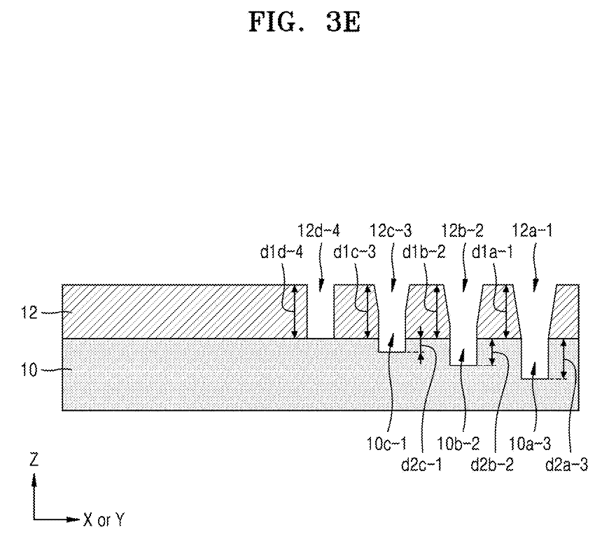

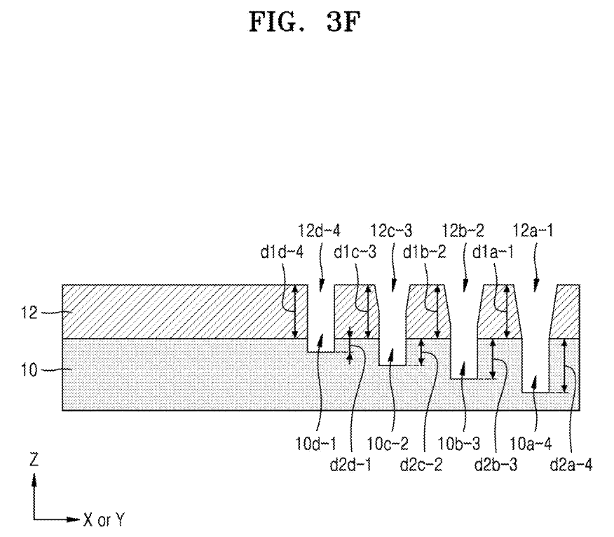

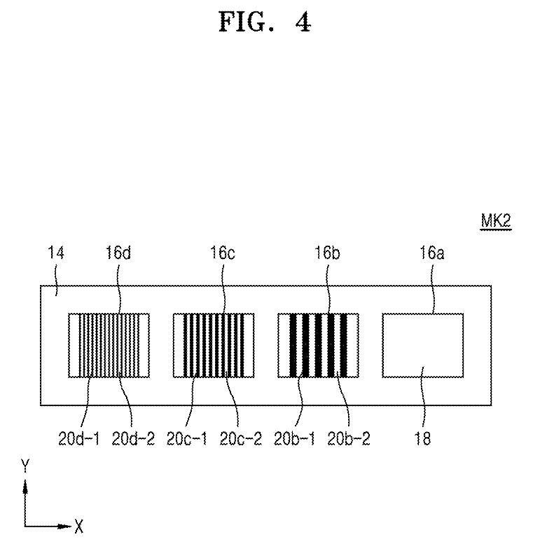

FIGS. 3A to 3F are cross-sectional views illustrating a method of manufacturing a semiconductor device, according to an embodiment, and FIG. 4 is a plan view illustrating a multi-tone reticle used in the exposure process of FIG. 3A.

In detail, the first, second, etc., described below include sequential meanings, but the inventive concept is not limited thereto. In FIGS. 3A to 3F, the X direction and the Y direction refer to a first horizontal direction and a second horizontal direction, respectively, and the Z direction may be a direction perpendicular to a plane defined by the X direction and the Y direction.

As shown in FIG. 1A, the mask layer 12 is formed on the pattern target layer 10. The pattern target layer 10 and the mask layer 12 are described above with reference to FIG. 1A, so a description thereof is omitted here.

As shown in FIGS. 3A, 3B, and 4, the mask layer 12 is exposed and developed using a multi-tone reticle MK2 including the white region (White, 16a) and first to third gray regions 16b, 16c, and 16d. The mask layer 12 may be exposed by the light 13 of a lithography device.

The multi-tone reticle MK2 may include the white region 16a located on the mask substrate 14 and the first to third gray regions 16b, 16c, and 16d. The mask substrate 14 may be a black region through which the light (13 in FIG. 3A) does not pass. The white region 16a may be a region in which light (13 in FIG. 3A) passes fully through the multi-tone reticle MK2.

The white region 16a may include a light-transmitting pattern 18. The first to third gray regions 16b, 16c, and 16d may be regions in which a portion of the light (13 in FIG. 3B) passes through the multi-tone reticle MK2. The first gray region 16b may include a plurality of first slit line patterns 20b-1 and first space patterns 20b-2 positioned between the first slit line patterns 20b-1.

The second gray region 16c may include a plurality of second slit line patterns 20c-1 and second space patterns 20c-2 positioned between the second slit line patterns 20c-1. The third gray region 16d may include a plurality of third slit line patterns 20d-1 and third space patterns 20d-2 positioned between the third slit line patterns 20d-1.

The widths of the second slit line patterns 20c-1 and the second space patterns 20c-2 may be less than the widths of the first slit line patterns 20b-1 and the first space patterns 20b-2, respectively. The widths of the third slit line patterns 20d-1 and the third space patterns 20d-2 may be less than the widths of the second slit line patterns 20c-1 and the second space patterns 20c-2, respectively.

The white region 16a may be a region with a large amount of light transmittance that exposes the mask layer 12. The first to third gray regions 16b, 16c, and 16d may be regions in which the amount of light transmittance for exposing the mask layer 12 is sequentially less than that of the white region 16a. In some embodiments, the amount of light transmittance of the white region 16a may be 100%, the amount of light transmittance of the first gray region 16b may be between 60% and 80% (e.g., 75%), the amount of light transmittance of the second gray region 16c may be between 40% and 60% (e.g., 50%), and the amount of light transmittance of the third gray region 16d may be between 20% and 40% (e.g., 25%).

As shown in the light intensity graph of FIG. 3A, when exposing the mask layer 12 by the light 13 of a lithography device, a portion of the multi-tone reticle MK2 through which the light 13 does not transmit is indicated in black, and a portion of the multi-tone reticle MK2 through which the light 13 transmits is indicated in white.

In addition, a portion in which the light 13 passes through the first gray region 16b of the multi-tone reticle MK2 is indicated as gray Gray1, a portion in which the light 13 passes through the second gray region 16c of the multi-tone reticle MK2 is indicated as gray Gray2, and a portion in which the light 13 passes through the third gray region 16d of the multi-tone reticle MK2 is indicated as gray Gray3. The light intensity may be greater in white than in Gray1 to Gray3. The light intensity may decrease in the order of Gray1, Gray2, and Gray3.

After the mask layer 12 is exposed to the light 13 of a lithography device, when a development process is performed, a first mask pattern region 12a-1 and second to fourth preliminary mask pattern regions 12b-1, 12c-1, and 12d-1 may be formed as shown in FIGS. 3A and 3B. The first mask pattern region 12a-1 may be formed to correspond to the white region 16a of the multi-tone reticle MK1.

The first mask pattern region 12a-1 may expose the pattern target layer 10 and may have a first thickness d1a-1. The second preliminary mask pattern region 12b-1 may not expose the pattern target layer 10 and may have a second sub-thickness d1b-1 that is less than the first thickness d1a-1.

The third preliminary mask pattern region 12c-1 may not expose the pattern target layer 10 and may have a third sub-thickness d1c-1 that is less than the second sub-thickness d1b-1. The fourth preliminary mask pattern region 12d-1 may not expose the pattern target layer 10 and may have a fourth sub-thickness d1d-1 that is less than the third sub-thickness d1c-1.

As shown in FIGS. 3C to 3F, first to fourth patterns 10a-4, 10b-3, 10c-2, and 10d-1 are formed within the pattern target layer 10. The pattern target layer 10 located below the first mask pattern region 12a-1, and the mask layer 12 and the pattern target layer 10 located below the second to fourth preliminary mask pattern regions 12b-1, 12c-1, and 12d-1 are etched to form first to fourth patterns 10a-4, 10b-3, 10c-2, and 10d-1 respectively having sequentially sized first to fourth depths d2a-4, d2b-3, d2c-2, and d2d-1 (e.g., which depths get sequentially smaller).

The formation process of the first to fourth patterns 10a-4, 10b-3, 10c-2, and 10d-1 is described in detail as follows. The operation of forming the first to fourth patterns 10a-4, 10b-3, 10c-2, and 10d-1 may include an operation of forming the second to fourth mask pattern regions 12b-2, 12c-3, and 12d-4 and an operation of etching the pattern target layer 10 by using the first to fourth mask pattern regions 12a-1, 12b-2, 12c-3, and 12d-4 as an etch mask. The second to fourth mask pattern regions 12b-2, 12c-3, and 12d-4 may be regions formed to correspond to the first to third gray regions 16b, 16c, and 16d, respectively.

As shown in FIG. 3C, the pattern target layer 10 located below the first mask pattern region 12a-1 is etched to form the first preliminary pattern 10a-1. The first preliminary pattern 10a-1 may have a first sub-depth d2a-1. It should be noted, a sub-depth may refer to a depth that may occur during an intermediate process and may become deeper during later processes. In addition, the mask layer 12 remaining below the second preliminary mask pattern region (12b-1 of FIG. 3B) is further etched to form the second mask pattern region 12b-2 that exposes the pattern target layer 10. The second mask pattern region 12b-2 may have a second thickness d1b-2. The second thickness d1b-2 may be the same as the first thickness d1a-1.

In the manufacturing process of FIG. 3C, the mask layer 12 remaining below the third preliminary mask pattern region (12c-1 of FIG. 3B) and the fourth preliminary mask pattern region (12d-1 of FIG. 3B) is further etched. The third preliminary mask pattern region (12c-1 in FIG. 3B) and the fourth preliminary mask pattern region (12d-1 in FIG. 3B) may be changed to the third preliminary mask pattern region 12c-2 and the fourth preliminary mask pattern region 12d-2, respectively. The third preliminary mask pattern region 12c-2 and the fourth preliminary mask pattern region 12d-2 may have an increased third sub-thickness d1c-2 and an increased fourth sub-thickness d1d-2, respectively.

As illustrated in FIG. 3D, the pattern target layer 10 located below the first preliminary pattern (10a-1 of FIG. 3C) is further etched, and the pattern target layer 10 located below the second mask pattern region (12b-2 of FIG. 3C) is etched to form the second preliminary pattern 10b-1.

The second preliminary pattern 10b-1 may have a second sub-depth d2b-1. The first preliminary pattern (10a-1 in FIG. 3C) is changed to the first preliminary pattern 10a-2. The first preliminary pattern 10a-2 may have an increased first sub-depth d2a-2.

In addition, the mask layer 12 remaining below the third preliminary mask pattern region 12c-2 is further etched to form the third mask pattern region 12c-3 that exposes the pattern target layer 10. The third mask pattern region 12c-3 may have a third thickness d1c-3. The third thickness d1c-3 may be equal to the second thickness d1b-2.

In the manufacturing process of FIG. 3D, the mask layer 12 remaining below the fourth preliminary mask pattern region (12d-2 of FIG. 3C) is further etched. The fourth preliminary mask pattern region (12d-2 in FIG. 3C) may be changed to the fourth preliminary mask pattern region 12d-3. The fourth preliminary mask pattern region 12d-3 may have an increased fourth sub-thicknessd1d-3.

As shown in FIG. 3E, the pattern target layer 10 located below the first preliminary pattern (10a-2 of FIG. 3d) and the second preliminary pattern (10b-1 of FIG. 3d) is further etched. The first preliminary pattern (10a-2 in FIG. 3d) and the second preliminary pattern (10b-1 in FIG. 3d) are changed to the first preliminary pattern 10a-3 and the second preliminary pattern 10b-2, respectively. The first preliminary pattern 10a-3 and the second preliminary pattern 10b-2 may have an increased first sub-depth d2a-3 and an increased second sub-depthd2b-2, respectively.

The pattern target layer 10 located below the third mask pattern region (12c-3 in FIG. 3d) is etched to form the third preliminary pattern 10c-1. The mask layer 20 remaining below the fourth preliminary mask pattern region (12d-3 in FIG. 3d) is further etched to form the fourth mask pattern region 12d-4 that exposes the pattern target layer 10. The fourth mask pattern region 12d-4 may have a fourth thickness d1d-4. The fourth thickness d1d-4 may be equal to the third thickness d1c-3.

As illustrated in FIG. 3F, the pattern target layer 10 located below the first mask pattern region 12a-1 and the first preliminary pattern (10a-3 of FIG. 3E) is further etched to form a first pattern 10a-4 having a first depth d2a-4.

The pattern target layer 10 located below the second mask pattern region (12b-2 in FIG. 3E) and the second preliminary pattern 10b-2 is further etched to form a second pattern 10b-3 having a second depth d2b-3 that is less than the first depth d2a-4.

The pattern target layer 10 located below the third mask pattern region (12c-3 in FIG. 3E) and the third preliminary pattern (10c-1 in FIG. 3E) is further etched to form a third pattern 10c-2 having a third depth d2c-2 that is less than the second depth d2b-3. The pattern target layer 10 located below the fourth mask pattern region (12d-4 in FIG. 3E) is etched to form a fourth pattern 10d-1 having a fourth depth d2d-1 that is less than the third depth d2c-2.

The first pattern 10a-4, the second pattern 10b-3, the third pattern 10c-2, and the fourth pattern 10d-1 may be trench patterns. When the pattern target layer 10 is a semiconductor substrate, the first pattern 10a-4, the second pattern 10b-3, the third pattern 10c-2, and the fourth pattern 10d-1 may be trench patterns formed within the semiconductor substrate.

Subsequently, by removing the mask layer 12, the method of manufacturing a layer of a semiconductor device including the first pattern 10a-4, the second pattern 10b-3, the third pattern 10c-2, and the fourth pattern 10d-1 may be completed. This method of manufacturing a semiconductor device may improve the reliability and electrical performance of the semiconductor device by forming four patterns with different depths through a single exposure and development process. For example, though FIGS. 3A-3F show different stages, the progression from the stage shown in FIG. 3A to the stage shown in FIG. 3F may be implemented using a single exposure and development process without the need for breaks within the exposure and development portion of the process and without the need for inserting additional mask layers or reticles. Therefore, multiple trenches of different depths can be formed in a single pattern-forming process simultaneously.

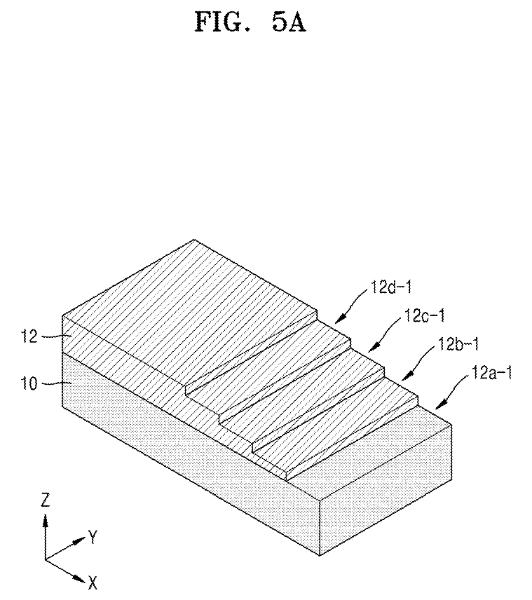

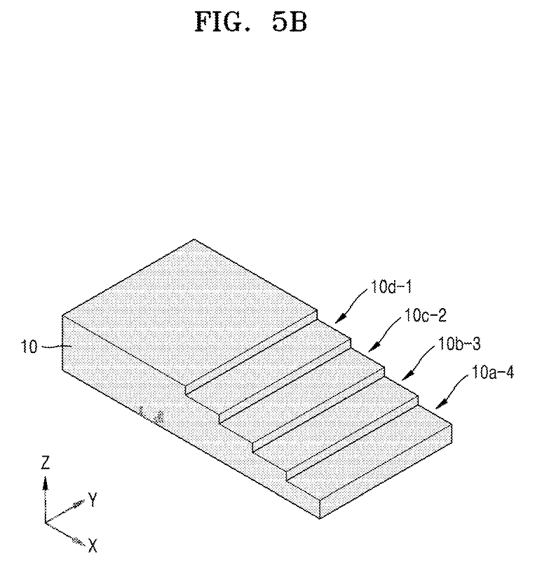

FIG. 5A is a perspective view illustrating mask pattern regions formed on a pattern target layer according to an embodiment, and FIG. 5B is a perspective view illustrating patterns formed according to an embodiment.

In detail, FIG. 5A shows the mask layer 12 including the mask pattern regions (i.e., 12a-1, 12b-1, 12c-1, and 12d-1) described above with reference to FIG. 3A. As shown in FIG. 5A, the mask pattern regions (i.e., 12a-1, 12b-1, 12c-1, and 12d-1) may be formed in a step-like shape along the X direction on the pattern target layer 10. In some embodiments, the mask pattern regions (i.e., 12a-1, 12b-1, 12c-1, and 12d-1) may be formed in a step-like shape along the Y direction, unlike FIG. 5A.

FIG. 5B shows the pattern target layer 10 including the first, second, third, and fourth patterns 10a-4, 10b-3, 10c-2, and 10d-1 described above with reference to FIG. 3F. As shown in FIG. 5B, the first, second, third, and fourth patterns 10a-4, 10b-3, 10c-2, and 10d-1 may be formed in a step-like shape along the X direction. In some embodiments, the first, second, third, and fourth patterns 10a-4, 10b-3, 10c-2, and 10d-1 may be formed in a step-like shape along the Y direction, unlike FIG. 5B.

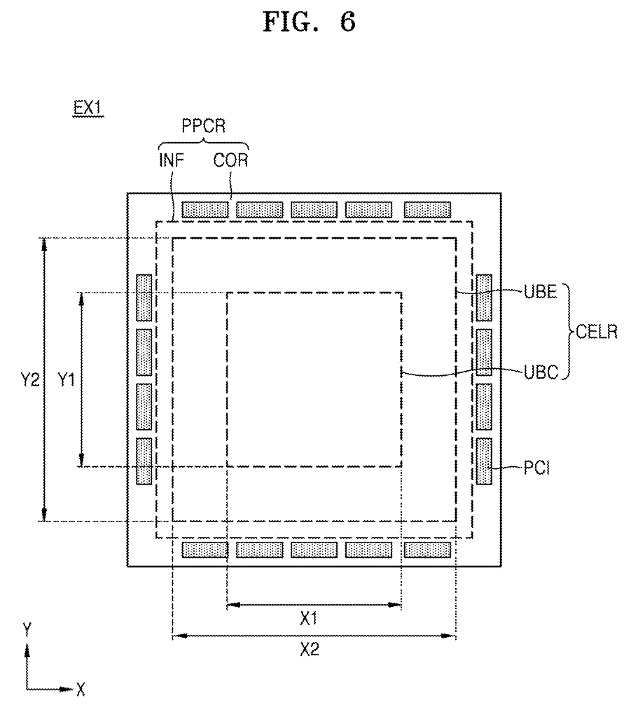

FIG. 6 is a plan view illustrating a semiconductor device EX1 that may be manufactured according to an embodiment.

In detail, the semiconductor device EX1 may include a cell region CELR and a peripheral circuit region PPCR surrounding the cell region CELR planarly. The cell region CELR may include a cell center region UBC and a cell edge region UBE surrounding the cell center region UBC planarly.

The cell edge region UBE may be arranged on one side (or two sides) of the cell center region UBC in the first horizontal direction (the X direction). The cell edge region UBE may be arranged on one side (or two sides) of the cell center region UBC in the second horizontal direction (the Y direction). The cell center region UBC and the cell edge region UBE may also be referred to as a unit block center region and a unit block edge region, respectively.

The cell region CELR may have an X2 length and a Y2 length in the first horizontal direction (the X direction) and the second horizontal direction (the Y direction), respectively. The X2 length and the Y2 length may be from several millimeters to tens of millimeters. In the cell region CELR, the cell center region UBC may have lengths of X1 and Y1 in the first horizontal direction (the X direction) and the second horizontal direction (the Y direction), respectively. A region excluding the cell center region UBC in the cell region CELR may be the cell edge region UBE.

In some embodiments, the length of the cell edge region UBE may be less than or equal to 5% of the length of the cell region CELR. For example, the cell edge region UBE may have a length X2-X1 obtained by subtracting the length X1 of the cell center region UBC in the first horizontal direction (the X direction) from the length X2 of the cell region CELR in the first horizontal direction (the X direction). The length X2-X1 may be equal to or less than 5% of the length X2. The cell edge region UBE may have a length Y2-Y1 obtained by subtracting the length Y1 of the cell center region UBC in the second horizontal direction (the Y direction) from the length Y2 of the cell region CELR in the second horizontal direction (the Y direction). The length Y2-Y1 may be equal to or less than 5% of the length Y2.

The peripheral circuit region PPCR may include an interface region INF surrounding the cell region CELR and a core region COR surrounding the interface region INF planarly. Peripheral circuits PCI may be placed in the core region COR. In the present embodiment, the interface region INF is included in the peripheral circuit region PPCR, but the interface region INF may also be included in the cell region CELR.

The semiconductor device EX1 may be a memory device. Accordingly, the cell region CELR described above may be a memory cell region. The memory device may be a dynamic random access memory (DRAM) device.

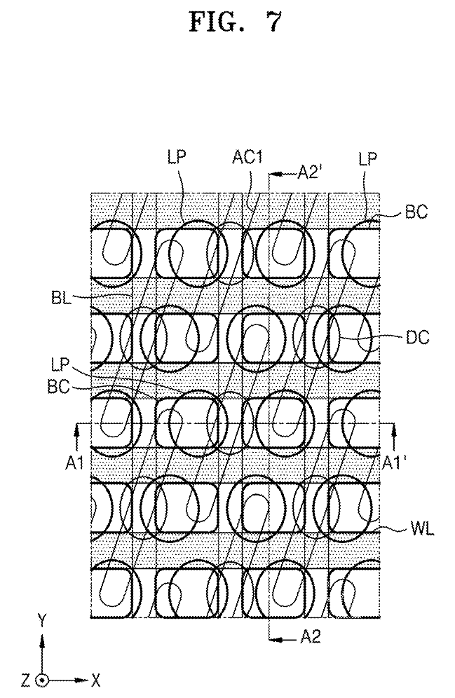

FIG. 7 is a schematic layout diagram illustrating main components of a cell region of a semiconductor device that may be manufactured by an embodiment according to the inventive concept.

In detail, FIG. 7 may be a diagram illustrating the main components of the cell region CELR of the semiconductor device EX1 of FIG. 6. The semiconductor device EX1 may include a plurality of active regions AC1 (or active patterns). The plurality of active regions AC1 (or active patterns) may be arranged in a diagonal direction with respect to the first horizontal direction (the X direction) and the second horizontal direction (the Y direction).

A plurality of word lines WL may extend parallel to each other in the first horizontal direction (the X direction) across the plurality of active regions AC1 (or active patterns). A plurality of bit lines BL may extend parallel to each other in the second horizontal direction (the Y direction) intersecting the first horizontal direction (the X direction) over the plurality of word lines WL. The plurality of bit lines BL may be connected to the plurality of active regions AC1 (or active patterns) via direct contacts DC.

A plurality of buried contact plugs BC may be formed between two adjacent bit lines BL among the plurality of bit lines BL. The buried contact plug BC may also be referred to as a buried contact. In some embodiments, the plurality of buried contact plugs BC may be arranged in a row in the first horizontal direction (the X direction) and the second horizontal direction (the Y direction).

A plurality of landing pads LP may be formed on the plurality of buried contact plugs BC. The landing pad LP may include a conductive material. The plurality of buried contact plugs BC and the plurality of landing pads LP may connect storage electrodes (or lower electrodes, not shown) of capacitors formed on top of the plurality of bit lines BL to the active regions AC1 (or active patterns). At least a portion of each of the plurality of landing pads LP may vertically overlap the buried contact plug BC.

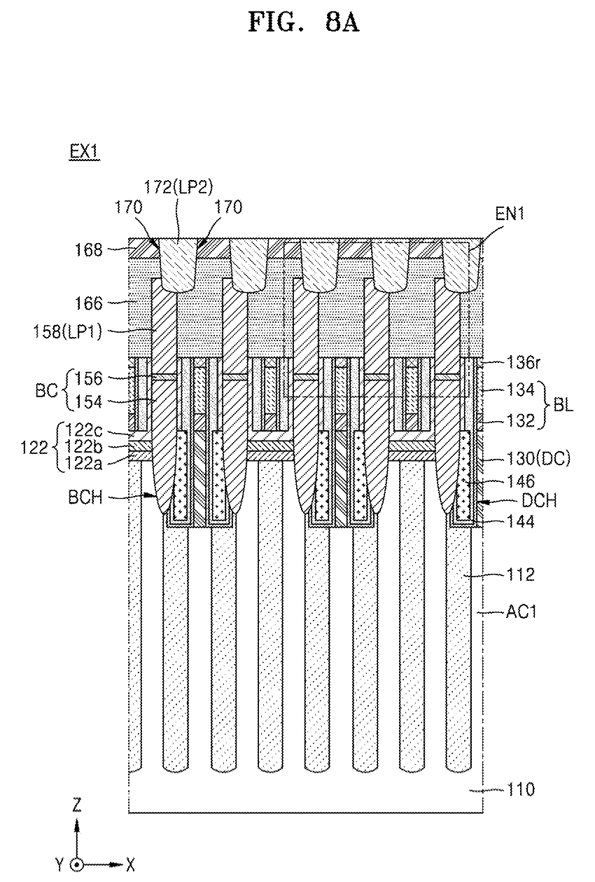

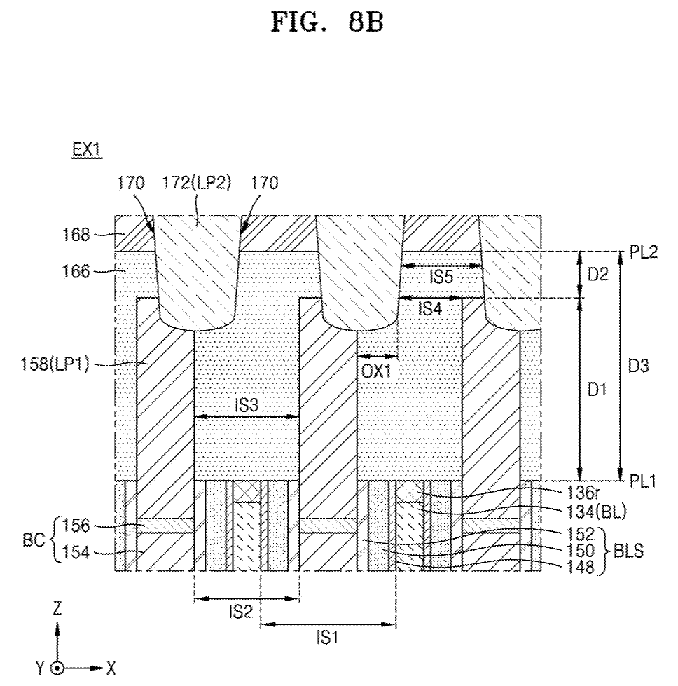

FIG. 8A is a cross-sectional view illustrating a semiconductor device that may be manufactured according to an embodiment, and FIG. 8B is an enlarged view of a portion of FIG. 8A.

In detail, FIG. 8A is a cross-sectional view in the first horizontal direction (the X direction) of FIG. 7, i.e., A1-A1'. FIG. 8B is an enlarged view of portion EN1 of FIG. 8A. In FIGS. 8A and 8B, the description given above with reference to FIG. 7 is briefly given or omitted.

The semiconductor device EX1 includes a semiconductor substrate 110 having a device isolation film 112 and a plurality of active regions AC1 (or active patterns). The active regions AC1 (or active patterns) may be easily formed through a single exposure and development process as described above. The device isolation film 112 may be formed on the semiconductor substrate 110. The device isolation film 112 may include a silicon oxide film.

The semiconductor substrate 110 may include silicon, for example, single crystal silicon, polycrystalline silicon, or amorphous silicon. In some embodiments, the semiconductor substrate 110 includes at least one selected from Ge, SiGe, SiC, GaAs, InAs, and InP.

In some embodiments, the semiconductor substrate 110 may include conductive regions, such as doped wells or doped structures. The device isolation film 112 may include an oxide film, a nitride film, or combinations thereof.

A buffer layer 122 is formed on the semiconductor substrate 110. The buffer layer 122 may be formed on upper surfaces of the plurality of active regions AC1 (or active patterns) and an upper surface of the device isolation film 112. The buffer layer 122 may include at least one of a silicon oxide film and a silicon nitride film. In some embodiments, the buffer layer 122 may include a first silicon oxide film 122a, a second silicon oxide film 122b, and a silicon nitride film 122c sequentially formed on the semiconductor substrate 110.

In some embodiments, depending on the manufacturing process, the first silicon oxide film 122a of the buffer layer 122 may not be formed. In this case, the buffer layer 122 may include the second silicon oxide film 122b and the silicon nitride film 122c. In some embodiments, depending on the manufacturing process, the first silicon oxide film 122a and the second silicon oxide film 122b of the buffer layer 122 may not be formed. In this case, the buffer layer 122 may include the silicon nitride film 122c.

The plurality of bit lines BL apart from each other in the first horizontal direction (the X direction) are formed on the buffer layer 122. In some embodiments, depending on the material forming the buffer layer 122, the bit line BL may be formed on a silicon oxide film or a silicon nitride film.

The plurality of bit lines BL may be connected to the active regions AC1 (or active patterns) via the direct contacts DC. The direct contacts DC may be provided in plurality. The plurality of direct contacts DC may be arranged apart from each other in the first horizontal direction (the X direction).

The direct contact DC is formed on a portion of the plurality of active regions AC1 (or active patterns). The direct contact DC is buried in a direct contact hole DCH that exposes the active regions AC1 (or active patterns) of the semiconductor substrate 110. A lower end portion of the direct contact DC may be positioned at a level lower than an upper surface of the semiconductor substrate 110 and buried within the semiconductor substrate 110.

In some embodiments, the direct contact DC may include a lower conductive pattern 130. The lower conductive pattern 130 may include a polysilicon film doped with impurities, such as boron (B), arsenic (As), or phosphorus (P). In some embodiments, the lower conductive pattern 130 may include Si, Ge, W, WN, Co, Ni, Al, Mo, Ru, Ti, TiN, Ta, TaN, Cu, or combinations thereof.

Each of the plurality of bit lines BL may include an intermediate conductive pattern 132 and an upper conductive pattern 134 formed sequentially on the direct contact DC. An insulating capping pattern 136r is formed on each of the plurality of bit lines BL. The insulating capping pattern 136r may be placed on the upper conductive pattern 134. An upper surface of the lower conductive pattern 130 may be flush with an upper surface of the direct contact DC.

Although FIG. 8A illustrates a dual-conductive layer structure in which the plurality of bit lines BL include the intermediate conductive pattern 132 and the upper conductive pattern 134, the inventive concept is not limited thereto.

For example, the plurality of bit lines BL may be described as including the lower conductive pattern 130, the intermediate conductive pattern 132, and the upper conductive pattern 134. The plurality of bit lines BL may be formed as a single conductive pattern or as a stack structure of a plurality of conductive patterns including quadruple conductive patterns or more.

In some embodiments, the intermediate conductive pattern 132 may include a barrier metal layer. In some embodiments, the upper conductive pattern 134 may include a metal layer. In some embodiments, the intermediate conductive pattern 132 and the upper conductive pattern 134 may include films including Ti, TiN, TiSiN, tungsten (W), WN, tungsten silicide (WSix), tungsten silicon nitride (WSixNy), ruthenium (Ru), or combinations thereof.

For example, the intermediate conductive pattern 132 may include a TiN film and/or a TiSiN film, and the upper conductive pattern 134 may include tungsten (W). In some embodiments, the insulating capping pattern 136 may include a silicon nitride film.

The plurality of buried contact plugs BC may be arranged on the semiconductor substrate 110. The buried contact plugs BC may also be simply referred to as contact plugs. The plurality of buried contact plugs BC may be arranged apart in the first horizontal direction (the X direction). The buried contact plug BC may have a pillar shape extending in the vertical direction (the Z direction) in the space between the plurality of bit lines BL. The plurality of buried contact plugs BC may contact active regions AC1 (or active patterns).

The buried contact plug BC is buried in a buried contact hole BCH that exposes the active regions AC1 (or active patterns) of the semiconductor substrate 110. A lower end portion of the buried contact plug BC may be positioned at a level lower than that of the upper surface of the semiconductor substrate 110 and buried within the semiconductor substrate 110.

The buried contact plug BC may include a semiconductor material doped with impurities, such as boron (B), arsenic (As), or phosphorus (P), a metal, a conductive metal nitride, or combinations thereof. In some embodiments, the buried contact plug BC may include a plug conductive layer 154 and a plug metal silicide layer 156.

In some embodiments, the plug conductive layer 154 may include a semiconductor material doped with impurities, such as boron (B), arsenic (As), or phosphorus (P). In some embodiments, the plug metal silicide layer 156 may include cobalt silicide, nickel silicide, or manganese silicide.

One direct contact DC and a pair of buried contact plugs BC facing each other with the one direct contact DC therebetween may be respectively connected to different active regions AC1 (or active patterns) among the plurality of active regions AC1 (or active patterns).

The semiconductor device EX1 may include a first inner spacer 144 and a gap fill insulating pattern 146 located between the plurality of direct contacts DC and the plurality of buried contact plugs BC. The first inner spacer 144 may be formed on a sidewall of the direct contact DC and the bottom of the direct contact hole DCH. In some embodiments, the first inner spacer 144 may include a silicon nitride layer.

The gap fill insulating pattern 146 may be formed on a lower sidewall of the buried contact plug BC and a sidewall of the first inner spacer 144. In some embodiments, the gap fill insulating pattern 146 may include a silicon oxide layer.

The semiconductor device EX1 may include a plurality of spacer structures BLS located between the bit line BL and the buried contact plug BC, as illustrated in FIG. 8B. The spacer structure BLS may include a second inner spacer 148, an intermediate spacer 150, and an outer spacer 152. The intermediate spacer 150 may be located between the second inner spacer 148 and the outer spacer 152. The second inner spacer 148 may include the same material as that of the first inner spacer 144. In some embodiments, the intermediate spacer 150 may include a silicon oxide layer. In some embodiments, the outer spacer 152 may include a silicon nitride layer.

A plurality of first landing pads LP1 may be formed above the plurality of buried contact plugs BC. The plurality of first landing pads LP1 may be arranged apart from each other in the first horizontal direction (the X direction) on the plurality of buried contact plugs BC. The first landing pad LP1 protrudes from a surface of the insulating capping pattern 136r above the bit line BL.

The first landing pad LP1 may be connected to the buried contact plug BC. The first landing pad LP1 may include a lower conductive pattern 158. The lower conductive pattern 158 may include doped polysilicon, metal, metal silicide, conductive metal nitride, or combinations thereof. In some embodiments, the lower conductive pattern 158 may include tungsten (W).

The semiconductor device EX1 may include a landing insulating layer 166 covering upper portions of the plurality of first landing pads LP1, while surrounding upper sidewalls of the plurality of protruding first landing pads LP1. The landing insulating layer 166 may fill a separation space around the plurality of protruding first landing pads LP. The plurality of protruding first landing pads LP may be electrically insulated from each other by the landing insulating layer 166.

In some embodiments, the landing insulating layer 166 may include a material having lower permittivity than that of a silicon nitride layer. In some embodiments, the landing insulating layer 166 may include a silicon oxide film or a silicon oxycarbide (SiOC) film.

A stopper insulating layer 168 may be placed on the landing insulating layer 166. In some embodiments, a stopper insulating layer 168 may include a silicon nitride layer. A plurality of second landing pads LP2 are arranged, which are electrically connected to the first landing pads LP1.

The second landing pad LP2 may include an upper conductive pattern 172. The upper conductive pattern 172 may include doped polysilicon, metal, metal silicide, conductive metal nitride, or combinations thereof. In some embodiments, the upper conductive pattern 172 may include tungsten (W).

The plurality of second landing pads LP2 may be arranged apart from each other in the first horizontal direction (the X direction) on the first landing pad LP1. The second landing pad LP2 may be buried in a landing opening hole 170 formed in the landing insulating layer 166 through the stopper insulating layer 168. Accordingly, the second landing pad LP2 may be electrically connected to the first landing pad LP1.

Here, the arrangement and mutual relationship of the bit line BL, the buried contact plug BC, the first landing pad LP1, the second landing pad LP2, and the landing insulating layer 166 are described with reference to FIG. 8B.

In detail, the plurality of bit lines BL are arranged at a first separation distance IS1 in the first horizontal direction (the X direction). The plurality of buried contact plugs BC are arranged at a second separation distance IS2 in the first horizontal direction (the X direction). The buried contact plug BC may be placed between two bit lines BL in the first horizontal direction (the X direction).

The plurality of first landing pads LP1 may be formed to protrude from a first horizontal line PL1 on an upper surface of the insulating capping pattern 136r on the bit line BL. The first landing pad LP1 protrudes by a first vertical distance D1 from the first horizontal line PL1 on an upper surface of the insulating capping pattern 136r on the bit line BL. A vertical short between the second landing pad LP2 and the buried contact plug BC located below the second landing pad LP2 may be suppressed due to the first vertical distance D1.

The plurality of first landing pads LP1 are apart from each other by a third separation distance IS3 in the first horizontal direction (the X direction). A horizontal short between two adjacent first landing pads LP1 may be suppressed due to the third separation distance IS3.

The landing insulating layer 166 may be arranged between the first horizontal line PL1 positioned at a first vertical distance D1 in the direction of the buried contact plug BC from the upper surface of the first landing pad LP1 and a second horizontal line PL2 positioned at a second vertical distance D2 in the direction of the stopper insulating layer 168 from the upper surface of the first landing pad LP1. A vertical distance between the first horizontal line PL1 and the second horizontal line PL2 may be a third vertical distance D3.

As described above, the landing insulating layer 166 may include a material having a lower permittivity than the silicon nitride layer, such as a silicon oxide or a silicon oxycarbide (SiOC) film. In this manner, parasitic capacitance between the plurality of first landing pads LP1 or second landing pads LP2 may be reduced.

The plurality of second landing pads LP2 penetrate the stopper insulating layer 168 and are buried in the landing opening holes 170 in a portion of the landing insulating layer 166. The landing opening hole 170 may be formed using a photolithography process after forming the landing insulating layer 166 and the stopper insulating layer 168. A separation distance between the plurality of second landing pads LP2 may be a fifth separation distance IS5. A horizontal short between two adjacent second landing pads LP2 may be suppressed due to the fifth separation distance IS5. The second landing pad LP2 is formed by burying a conductive layer for the second landing pad in the landing opening hole 170. Accordingly, the second landing pad LP2 may be formed reliably in the manufacturing process.

The second landing pad LP2 may be horizontally moved by a first offset OX1 in the first horizontal direction (the X direction) from the first landing pad LP1 to be positioned. A portion of the second landing pad LP2 may not vertically overlap the first landing pad LP1. Accordingly, a separation distance between the second landing pad LP2 and the first landing pad LP1 may be a fourth separation distance IS4 that is less than the fifth separation distance IS5.

Although the fourth separation distance IS4 is less than the fifth separation distance IS5, a horizontal short between the plurality of second landing pads LP2 or between adjacent first landing pads LP1 may be suppressed. The second landing pad LP2 may be electrically connected in the vertical direction to the first landing pad LP1.

As described above, the semiconductor device EX1 may improve reliability and electrical performance by forming the active regions AC1 (or active patterns) through a single exposure and development process. One of more of the photolithography processes used to form patterns of the semiconductor device described in connection with FIGS. 6 to 8A may use a reticle and process such as described in connection with FIGS. 1A-5. In addition, the semiconductor device EX1 may reliably implement a vertical connection relationship between the buried contact plug BC and the first and second landing pads LP1 and LP2 and reduce parasitic capacitance between the first and second landing pads LP1 and LP2.

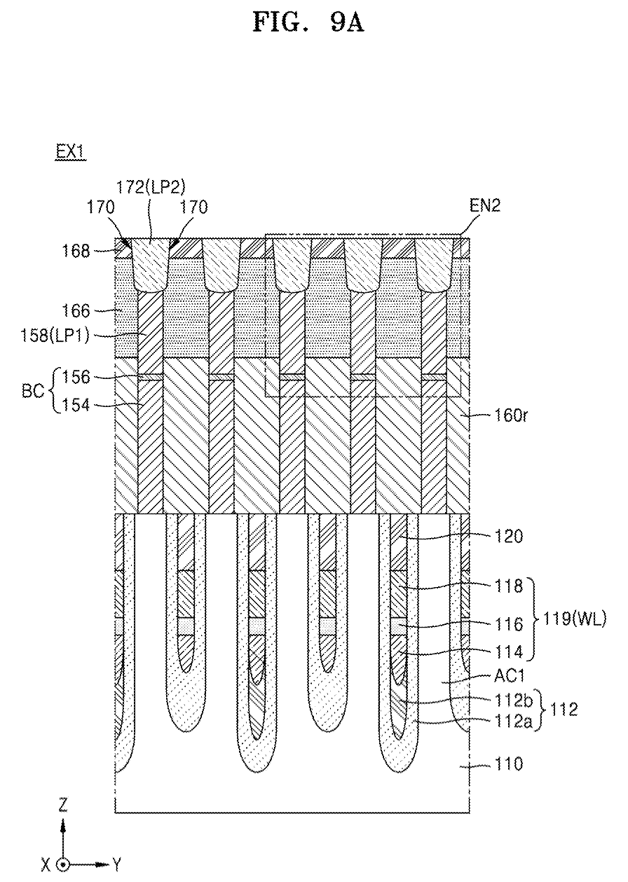

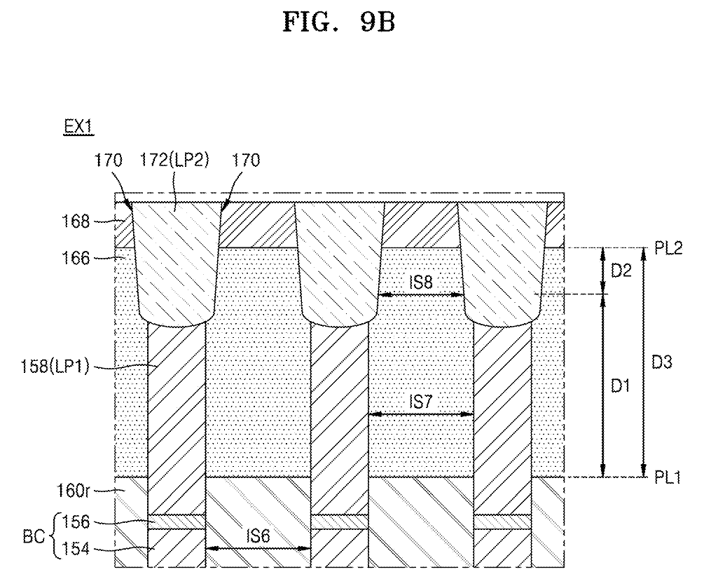

FIG. 9A is a cross-sectional view illustrating the semiconductor device EX1 that may be manufactured according to an embodiment, and FIG. 9B is an enlarged view of a portion of FIG. 9A.

In detail, FIG. 9A is a cross-sectional view in the second horizontal direction (the Y direction) of FIG. 7, i.e., A2-A2'. FIG. 9B is an enlarged view of portion EN2 of FIG. 9A. In FIGS. 9A and 9B, the description given above with reference to FIGS. 7, 8A, and 8B is briefly given or omitted.

The semiconductor device EX1 includes the semiconductor substrate 110 in which the plurality of active regions AC1 (or active patterns) are defined by a plurality of device isolation films 112. The device isolation film 112 may be formed on the semiconductor substrate 110. The device isolation film 112 may include a silicon oxide film 112a and a silicon nitride film 112b.

A plurality of word lines 119 may be arranged within the device isolation film 112. The plurality of word lines 119 are apart from each other in the second horizontal direction (the Y direction). The word line 119 may be buried in a word line trench formed in the semiconductor substrate 110.

The word line 119 may include gate conductive layers 114, 116, and 118. The gate conductive layers 114, 116, and 118 may include a lower gate conductive layer 114, an intermediate gate conductive layer 116, and an upper gate conductive layer 118. A gate dielectric film (not shown) may be formed below the gate conductive layers 114, 116, and 118, for example, the lower gate conductive layer 114.

The gate dielectric film may include at least one selected from a silicon oxide film, a silicon nitride film, a silicon oxynitride film, an oxide/nitride/oxide (ONO) film, or a high-k dielectric film having a higher dielectric constant than that of the silicon oxide film. The gate conductive layers 114, 116, and 118 may include Ti, TiN, Ta, TaN, W, WN, TiSiN, WSiN, or combinations thereof.

A gate cap layer 120 may be formed on the upper gate conductive layer 118 among the gate conductive layers 114, 116, and 118. In some embodiments, the gate cap layer 120 may include a silicon nitride layer. The plurality of buried contact plugs BC may be formed on the plurality of active regions AC1 (or active patterns).

The plurality of buried contact plugs BC may be arranged apart from each other in the second horizontal direction (the Y direction). In some embodiments, the buried contact plug BC may include a plug conductive layer 154 and a plug metal silicide layer 156.

A plurality of fence insulating layers 160r are formed on the gate cap layer 120 and the device isolation film 112. The fence insulating layers 160r are apart from each other in the second horizontal direction (the Y direction). In some embodiments, the fence insulating layer 160r may include a silicon nitride layer. The fence insulating layer 160r may be formed between the plurality of buried contact plugs BC.

The plurality of first landing pads LP1 may be formed above the plurality of buried contact plugs BC. The fence insulating layer 160r may be formed to cover a lower portion of the first landing pad LP1. The plurality of first landing pads LP1 may be arranged apart from each other in the second horizontal direction (the Y direction) on the plurality of buried contact plugs BC. The first landing pad LP1 protrudes from a surface of the fence insulating layer 160r.

The first landing pad LP1 may be connected to the buried contact plug BC. The first landing pad LP1 may include the lower conductive pattern 158. The semiconductor device EX1 may include the landing insulating layer 166 covering upper portions of the plurality of first landing pads LP1, while surrounding upper sidewalls of the plurality of protruding first landing pads LP1.

The stopper insulating layer 168 may be placed on the landing insulating layer 166. The plurality of second landing pads LP2 are arranged on the plurality of first landing pads LP1 and are electrically connected to the first landing pads LP1. The second landing pad LP2 may include the upper conductive pattern 172.

The plurality of second landing pads LP2 may be arranged apart from each other in the second horizontal direction (the Y direction) on the first landing pad LP1. The second landing pad LP2 may be buried in the landing opening hole 170 formed in the landing insulating layer 166 by penetrating the stopper insulating layer 168.

Here, the arrangement and mutual relationship of the buried contact plug BC, the first landing pad LP1, the second landing pad LP2, and the landing insulating layer 166 are described with reference to FIG. 9B.

In detail, the plurality of buried contact plugs BC are apart from each other at a sixth separation distance IS6 in the second horizontal direction (the Y direction). The buried contact plug BC may be placed between two bit lines BL in the second horizontal direction (the Y direction).

The plurality of first landing pads LP1 may be formed to protrude from the first horizontal line PL1 on the upper surface of the fence insulating layer 160r. The first horizontal line PL1 may be at the same level as that of the first horizontal line PL1 described above with reference to FIG. 3B.

The first landing pad LP1 protrudes by a first vertical distance D1 from the first horizontal line PL1 on the upper surface of the fence insulating layer 160r. A vertical short between the second landing pad LP2 and the buried contact plug BC located below the second landing pad LP2 may be suppressed due to the first vertical distance D1.

The plurality of first landing pads LP1 are arranged at a seventh separation distance IS7 in the second horizontal direction (the X direction). A horizontal short between two adjacent first landing pads LP1 may be suppressed due to the seventh separation distance IS7.

The landing insulating layer 166 may be arranged between the first horizontal line PL1 positioned at a first vertical distance D1 in the direction of the buried contact plug BC from the upper surface of the first landing pad LP1 and the second horizontal line PL2 positioned at a second vertical distance D2 in the direction of the stopper insulating layer 168 from the upper surface of the first landing pad LP1. The second horizontal line PL2 may be at the same level as that of the second horizontal line PL2 described above with reference to FIG. 3B. A vertical distance between the first horizontal line PL1 and the second horizontal line PL2 may be a third vertical distance D3.

As described above, the landing insulating layer 166 may include a material having a lower dielectric constant (e.g., permittivity) than the silicon nitride layer, such as a silicon oxide film or a silicon oxycarbide (SiOC) film. In this manner, parasitic capacitance between the plurality of first landing pads LP1 or second landing pads LP2 may be reduced.

The plurality of second landing pads LP2 penetrate the stopper insulating layer 168 and are buried in the landing opening holes 170 in a portion of the landing insulating layer 166. The landing opening hole 170 may be formed using a photolithography process after forming the landing insulating layer 166 and the stopper insulating layer 168. A separation distance between the plurality of second landing pads LP2 may be an eighth separation distance IS8. A horizontal short between two adjacent second landing pads LP2 may be suppressed due to the eighth separation distance IS8. The second landing pad LP2 is formed by burying a conductive layer for the second landing pad in the landing opening hole 170. Accordingly, the second landing pad LP2 may be formed reliably in the manufacturing process.

The second landing pad LP2 may vertically overlap the first landing pad LP1 without being offset in the second horizontal direction (the Y direction). A separation distance between the second landing pads LP2 may be an eighth separation distance IS8, which is approximately the same as the seventh separation distance IS7. Accordingly, a horizontal short between adjacent second landing pads LP2 or between adjacent first landing pads LP1 may be suppressed. The second landing pad LP2 may be electrically connected to the first landing pad LP1 in the vertical direction.

As described above, the semiconductor device EX1 may improve reliability and electrical performance by forming the active regions AC1 (or active patterns) through a single exposure and development process. For example, the active regions AC1 include trenches in which the device isolation film 112 and word lines 119 are formed to have different depths, and the single exposure and development process discussed previously may be used to form the different depth trenches. In addition, the semiconductor device EX1 may reliably implement a vertical connection relationship between the buried contact plug BC and the first and second landing pads LP1 and LP2 and reduce parasitic capacitance between the first and second landing pads LP1 and LP2.

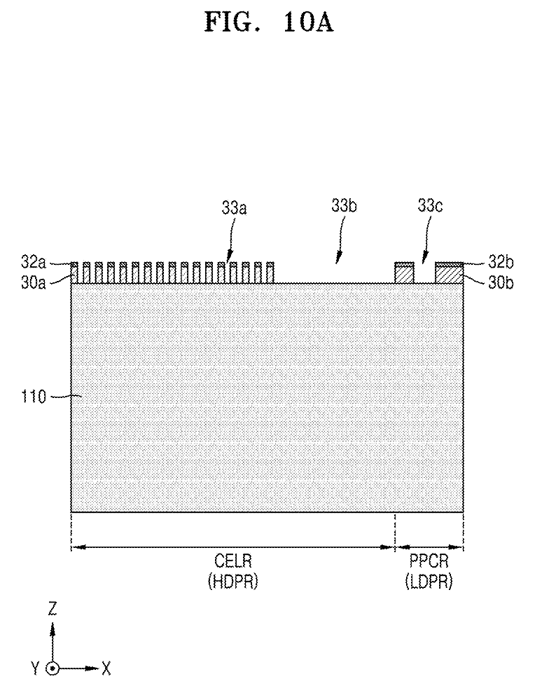

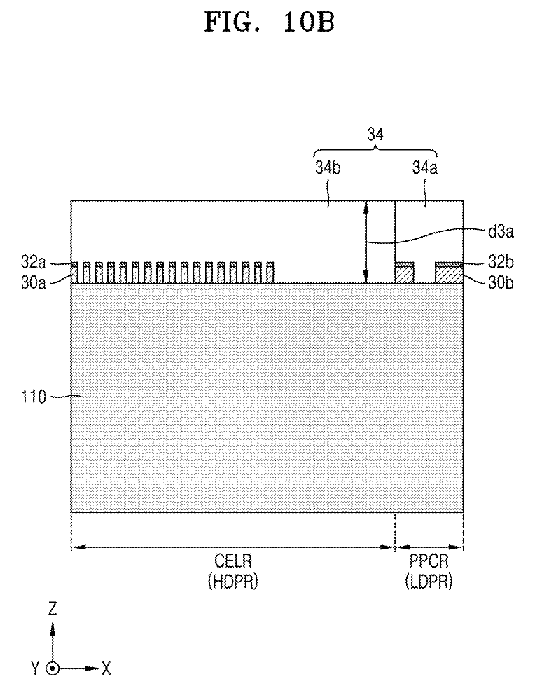

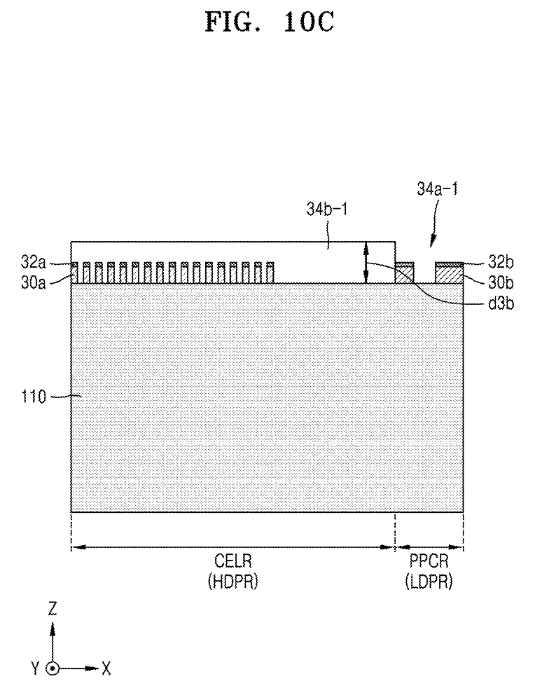

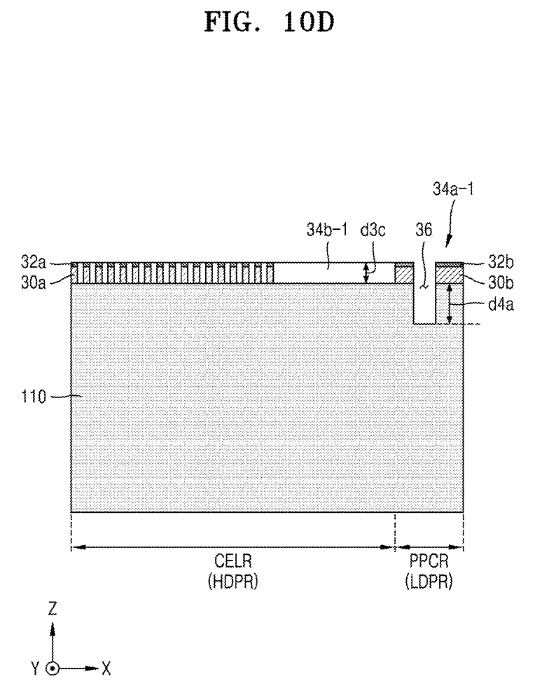

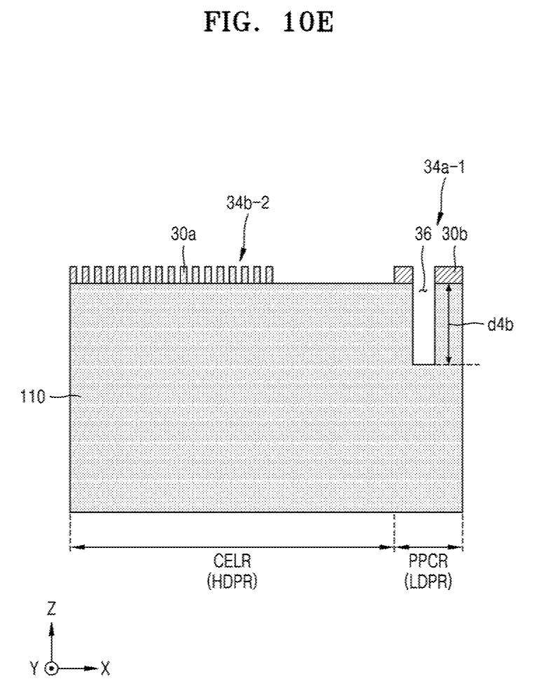

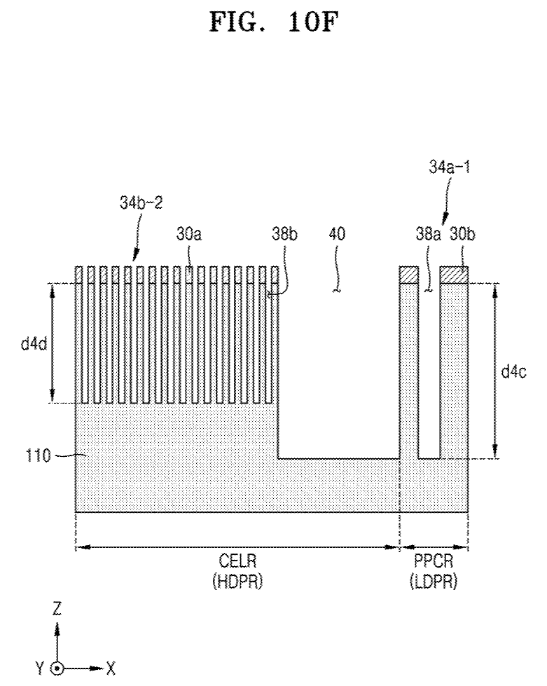

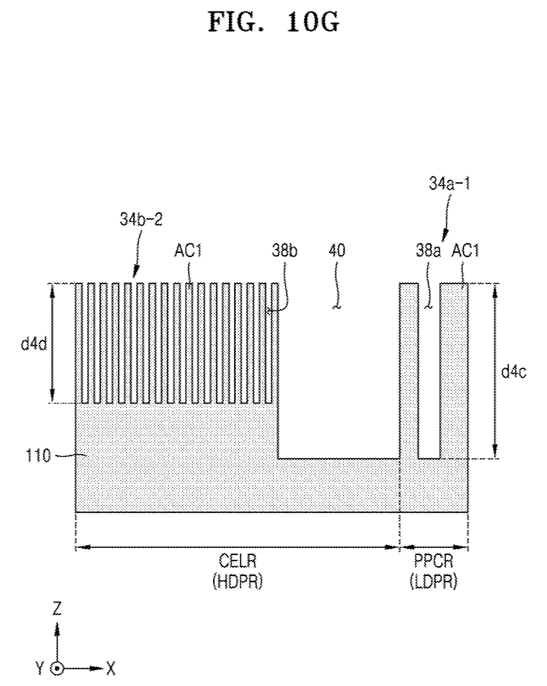

FIGS. 10A to 10G are cross-sectional views illustrating a method of manufacturing a semiconductor device, according to an embodiment.

Specifically, FIGS. 10A to 10G illustrate an embodiment of a method of forming the active regions AC1 (or active patterns) of the semiconductor device EX1 of FIGS. 6 to 9B. In FIGS. 10A to 10G, the description given above with reference to FIGS. 1A to 2 and FIGS. 6 to 9B are briefly given or omitted.

Referring to FIG. 10A, first and second high-density mask patterns 30a and 32a and first and second low-density mask patterns 30b and 32b are formed on the semiconductor substrate 110 having the cell region CELR and the peripheral circuit region PPCR, respectively. The first high-density mask pattern 30a may be formed of a first layer at a first vertical level. The second high-density mask pattern 32a may be formed on the first high-density mask pattern 30a and may be formed of a second layer at a second vertical level. The first low-density mask pattern 30b may be formed of a first layer at the first vertical level. The second low-density mask pattern 32b may be formed on the first low-density mask pattern 30b and may be formed of a second layer at the second vertical level. The first and second high-density mask patterns 30a and 32a may form individual patterns, each pattern formed as a protrusion or opening. The first and second low-density mask patterns 30b and 32b may form individual patterns, each formed as a protrusion or opening. The high-density mask patterns have a higher density than the low-density mask patterns, and thus “high-density” and “low-density” are used in relation to each other as relative terms throughout this specification. The semiconductor substrate 100 may be such a pattern target layer as described above. The peripheral circuit region PPCR may include the core region COR. The peripheral circuit region PPCR may be a region in which peripheral circuit transistors that operate the cell region CELR are formed.

The cell region CELR in which the first and second high-density mask patterns 30a and 32a are formed may be a high-density pattern formation region HDPR. The peripheral circuit region PPCR in which the first and second low-density mask patterns 30b and 32b are formed may be a low-density pattern formation region LDPR.

The first and second high-density mask patterns 30a and 32a may be formed by a multi-patterning process, for example, a dual patterning process or a quadruple patterning process. The first and second low-density mask patterns 30b and 32b may be formed by a multi-patterning process or a single patterning process.

The first and second high-density mask patterns 30a and 32a include individual patterns apart from each other in the first horizontal direction (the X direction). The first and second high-density mask patterns 30a and 32a include individual patterns that may have a width of several nanometers in the first horizontal direction. A narrow first opening 33a exposing a surface of the semiconductor substrate 110 may be formed between each individual pattern of the first and second high-density mask patterns 30a and 32a.

A wide second opening 33b exposing the surface of the semiconductor substrate 100 may be formed on one side of the first and second high-density mask patterns 30a and 32a. The first and second high-density mask patterns 30a and 32a may include a silicon oxide layer and a polysilicon layer, respectively (e.g., the first high-density mask pattern 30a may be a silicon oxide layer and the second high-density mask pattern 32a may be a polysilicon layer).

The first and second low-density mask patterns 30b and 32b include individual patterns apart from each other in the first horizontal direction (the X direction). The widths of the individual patterns of the first and second low-density mask patterns 30b and 32b may be greater than the widths of the individual patterns of the first and second high-density mask patterns 30a and 32a in the first horizontal direction.

The widths of the individual patterns of the first and second low-density mask patterns 30b and 32b may be several tens of nanometers. A third opening 33c exposing the surface of the semiconductor substrate 110 may be formed between two individual patterns of the first and second low-density mask patterns 30b and 32b. The first and second low-density mask patterns 30b and 32b may include a silicon oxide layer and a polysilicon layer, respectively (e.g., the first low-density mask pattern 30b may be a silicon oxide layer and the second low-density mask pattern 32b may be a polysilicon layer).

Referring to FIG. 10B, a mask layer 34 is formed on the first and second high-density mask patterns 30a and 32a and the low-density mask patterns 30b and 23b. In some embodiments, the mask layer 34 may be a photoresist layer. In some embodiments, the mask layer 34 may be a hard mask layer. In some embodiments, the mask layer 34 may be a spin on hard mask (SOH) layer.

Here, the SOH layer may include a material including a hydrocarbon compound or a derivative thereof having a relatively high carbon content of about 85 to 99 wt% based on the total weight. The mask layer 34 may have a first thickness d3a.

Subsequently, the mask layer 34 is exposed using the multi-tone reticle (MK1 of FIG. 2) including the white region (16a of FIG. 2) and the gray region (16c of FIG. 2) as described above with reference to FIGS. 1B and 2. In this manner, the mask layer 34 may be classified into a high exposure layer 34a formed to correspond to the white region (16a in FIG. 2) of the multi-tone reticle (MK1 in FIG. 2) and a low exposure layer 34b formed to correspond to the gray region (16c in FIG. 2) of the multi-tone reticle (MK1 in FIG. 2).

Referring to FIG. 10C, the high exposure layer (34a in FIG. 10B) and the low exposure layer (34b in FIG. 10B) are developed with a developer to selectively remove the high exposure layer (34a in FIG. 10B). In this manner, in the peripheral circuit region PPCR and the low-density pattern formation region LDPR, a first mask exposure pattern region 34a-1 exposing the semiconductor substrate 110 and the first and second low-density mask patterns 30b and 32b may be formed. The first mask exposure pattern region 34a-1 may be a region formed by exposing and developing the high exposure layer (34a in FIG. 10B) to correspond to the white region (16a in FIG. 2) of the multi-tone reticle MK1.

In addition, in the cell region CELR and the high-density pattern formation region HDPR, a second mask pattern region 34b-1 that does not expose the semiconductor substrate 110 and the first and second high-density mask patterns 30a and 32a may be formed. The second mask pattern region 34b-1 may be a region formed by exposing and developing the low exposure layer (34b in FIG. 10B) corresponding to the gray region (16c in FIG. 2) of the multi-tone reticle (MK1 in FIG. 2).

When the second mask pattern region 34b-1 is formed by developing the high exposure layer (34a of FIG. 10B) and the low exposure layer (34b of FIG. 10B), the second mask pattern region 34b-1 may have a second thickness d3b. The second thickness d3b may be less than the first thickness d3a of FIG. 10B.

Referring to FIG. 10D, the semiconductor substrate 110 located below the first mask exposure pattern region 34a-1 is etched using the second mask pattern region 34b-1 as an etch mask to form a first preliminary pattern 36. In the present embodiment, for convenience, only one individual first preliminary pattern 36 is illustrated, but if a plurality of first and second low-density mask patterns 30b and 32b are provided, the first preliminary pattern 36 may be formed in plurality.

At the time of forming the first preliminary pattern 36, the second mask pattern region 34b-1 may be etched to have a third thickness d3c. The third thickness d3c may be less than the second thicknessd3b of FIG. 10C. The first preliminary pattern 36 may have a first sub-depth d4a.

Referring to FIG. 10E, the second mask pattern region (34b-1 of FIG. 10D) is further etched to form a second mask exposure pattern region 34b-2 that exposes the first high-density mask patterns 30a and the semiconductor substrate 110. At the time of forming the second mask exposure pattern region 34b-2, the second high-density mask patterns 32a and the second low-density mask patterns 32b may be etched.

At the time of forming the second mask exposure pattern region 34b-2, the first preliminary pattern 36 of the first mask exposure pattern region 34a-1 may be further etched to have a second sub-depth d4b. The second sub-depth d4b may be greater than the first sub-depth d4a.

In the present embodiment, the formation of the second mask exposure pattern region 34b-2 and the first preliminary pattern 36 is described separately with reference to FIGS. 10D and 10E, but the manufacturing processes of FIGS. 10D and 10E may be performed in a single manufacturing process.

Referring to FIG. 10F, the semiconductor substrate 110 located below the first mask exposure pattern region 34a-1 and the first preliminary pattern (36 of FIG. 10E) is further etched to form a first pattern 38a having a first depthd4c. The semiconductor substrate 110 located below the first high-density mask patterns 30a in the second mask exposure pattern region 34b-2 is etched to form second patterns 38b having a second depth d4d that is less than the first depth d4c (e.g., including first individual patterns with spaces therebetween, wherein the spaces are formed by trenches having a first depth d4d).

According to the above example, the semiconductor substrate 110 is further etched using the first low-density mask patterns 30b of the first mask exposure pattern region 34a-1 and the first high-density mask patterns 30a of the second mask exposure pattern region 34b-2 as etch masks to form the first pattern 38a and the second patterns 38b. At the time of forming the first pattern 38a and the second patterns 38b, a third pattern 40 (e.g., a trench) having a large width may be formed in the boundary region of the cell region CELR and the peripheral circuit region PPCR.

The first pattern 38a, the second patterns 38b, and the third pattern 40 may be a first trench pattern, second trench patterns, and a third trench pattern, respectively. In addition, low-density active patterns AC1 are formed around the first pattern 38a of the first mask exposure pattern region 34a-1 or in or the first patterns 38a. In addition, the high-density active patterns AC1 are formed between the second patterns 38 of the second mask exposure pattern region 34b-2.

Referring to FIG. 10G, the method of manufacturing a semiconductor device including the process of forming the active regions AC1 (or active patterns) is completed by removing the first low-density mask patterns 30b and the first high-density mask patterns 30a.

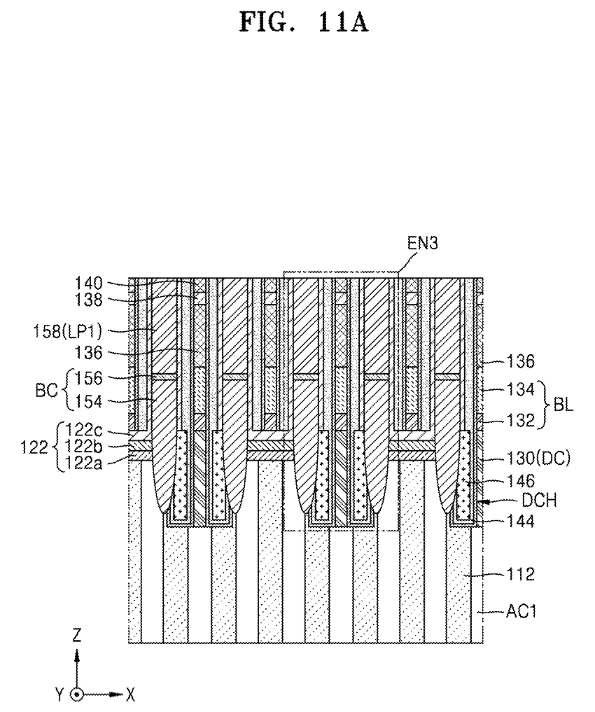

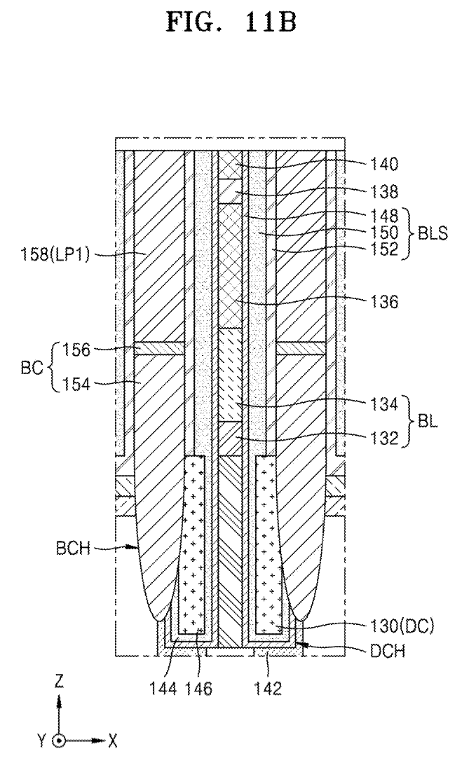

FIGS. 11A to 18 are cross-sectional views illustrating a method of manufacturing the semiconductor device EX1 illustrated in FIGS. 8A and 9A.

In detail, FIGS. 11A to 18 illustrate a method of manufacturing the semiconductor device (EX1 of FIGS. 6 to 9B) using a manufacturing process of the active regions AC1 (or active patterns) described above with reference to FIGS. 10A to 10G.

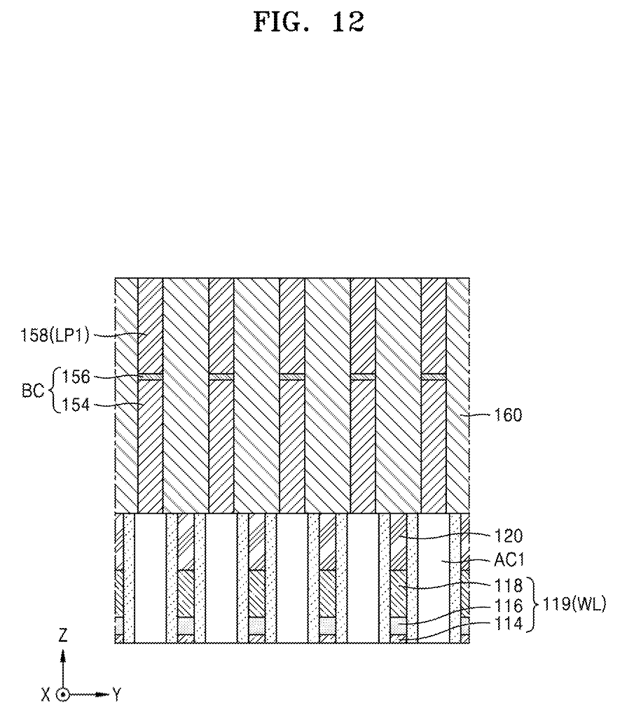

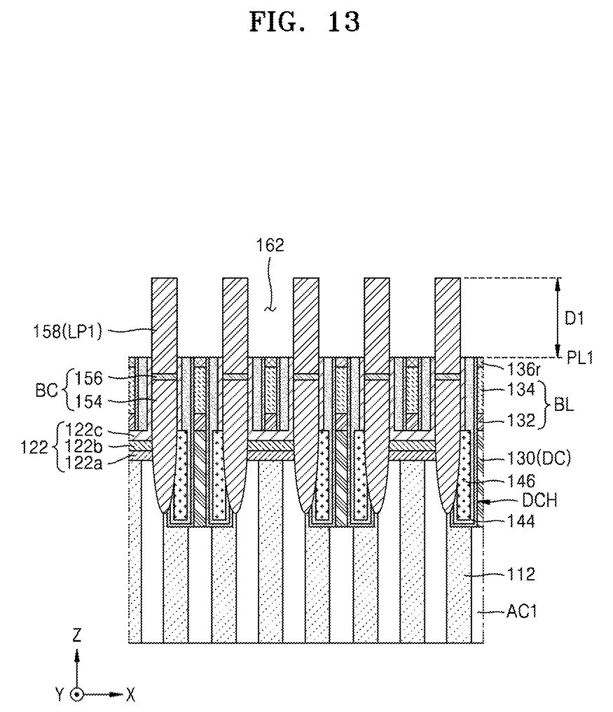

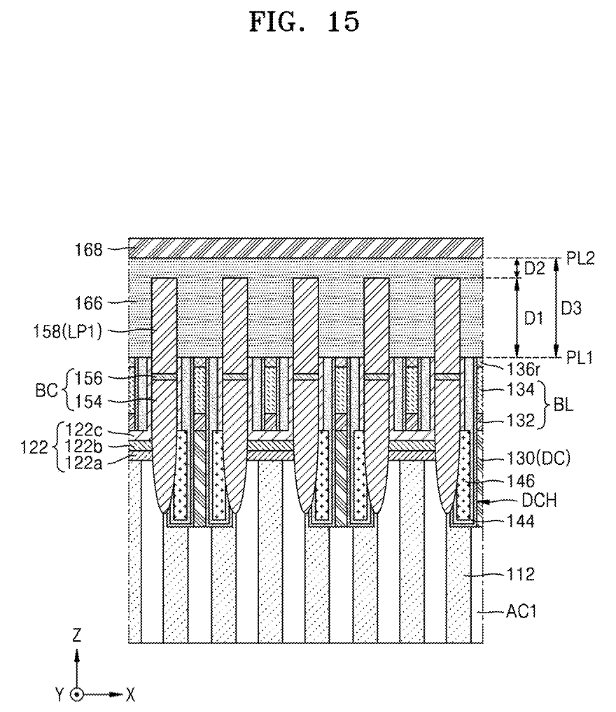

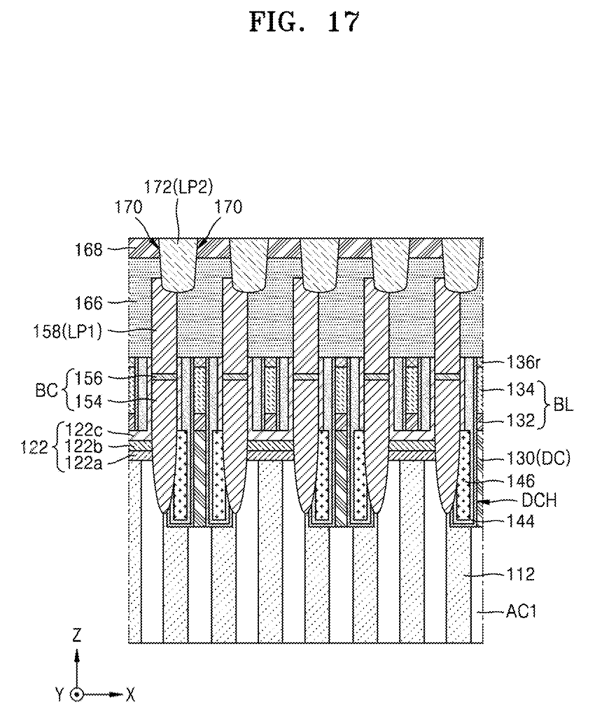

FIG. 11A, FIG. 13, FIG. 15, and FIG. 17 are cross-sectional views illustrating a manufacturing method in the first horizontal direction (the X direction), i.e., A1-A1' in FIG. 7. FIG. 11B is an enlarged view of portion EN3 of FIG. 11A. FIGS. 12, 14, and 16 are cross-sectional views illustrating a manufacturing method in the second horizontal direction (the Y direction), i.e., A2-A2' in FIG. 2. In FIGS. 11A to 18, the description given above with reference to FIGS. 8A to 9B is briefly given or omitted.

As shown in FIGS. 11A and 11B, a plurality of active regions AC1 (or active patterns) are formed in the semiconductor substrate (110 of FIG. 8A), and the device isolation film 112 is formed between the active regions AC1. The buffer layer 122 is formed on the active regions AC1 (or active patterns) and the device isolation film 112.

The lower conductive pattern 130, the intermediate conductive pattern 132, the upper conductive pattern 134, the first insulating capping pattern 136, the second insulating capping pattern 138, and the third insulating capping pattern 140 are formed on some of the active regions AC1 (or active patterns). In some embodiments, the second insulating capping pattern 138 and the third insulating capping pattern 140 may include or may be a silicon nitride layer.

The spacer structure BLS may be formed on opposite sides of the intermediate conductive pattern 132, the upper conductive pattern 134, the first insulating capping pattern 136, the second insulating capping pattern 138, and the third insulating capping pattern 140. The spacer structure BLS may include the second inner spacer 148, the intermediate spacer 150, and the outer spacer 152. The intermediate conductive pattern 132 and the upper conductive pattern 134 may form the bit line BL.

The lower conductive pattern 130 may form the direct contact DC. At the time of forming the lower conductive pattern 130, the device isolation film and active regions AC1 (or active patterns) around the lower conductive pattern 130 may be etched to form the direct contact hole DCH. The first inner spacer 144 and the gap fill insulating pattern 146 may be formed on the bottom and sidewall of the lower conductive pattern 130 of the direct contact hole DCH. The first inner spacer 144 and the second inner spacer 148 may be formed during the same process.

The plug conductive layer 154, the plug metal silicide layer 156, and the lower conductive pattern 158 are formed in the semiconductor substrate (110 of FIG. 8A) between the lower conductive pattern 130, the intermediate conductive pattern 132, and the upper conductive pattern 134 and the first insulating capping pattern 136, the second insulating capping pattern 138, and the third insulating capping pattern 140 in the first horizontal direction (the X direction).

The plug conductive layer 154 is formed within the buried contact hole BCH adjacent to the direct contact hole DCH through the buffer layer 122. The buried contact holes BCH may be formed on the active regions AC1 (or active patterns) within the semiconductor substrate (110 in FIG. 8A). The plug conductive layer 154 and the plug metal silicide layer 156 may form the buried contact plug BC. The lower conductive pattern 158 may form the first landing pad LP1.

As illustrated in FIG. 12, the plurality of word lines WL may be formed within the device isolation film 112. The word line WL may include the gate conductive layers 114, 116, and 118. The gate cap layer 120 may be formed on the upper gate conductive layer 118.

A plurality of buried contact plugs BC and lower conductive patterns 158 are formed on the active regions AC1 (or active patterns). A plurality of fence insulating material layers 160 apart from each other in the second horizontal direction (the Y direction) are formed between the plurality of buried contact plugs BC and the lower conductive pattern 158 on the gate cap layer 120 and a device isolation film 112. The fence insulating material layer 160 may include a silicon nitride layer.

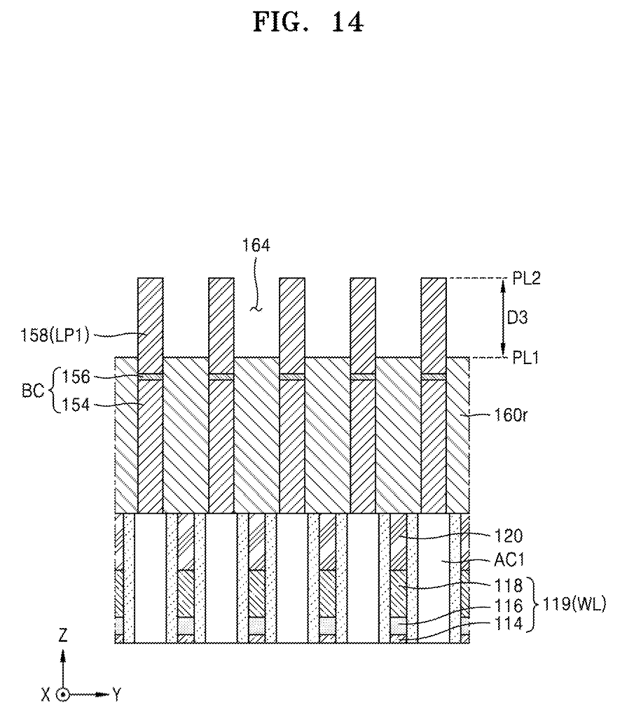

Referring to FIGS. 13 and 14, the third insulating capping pattern (140 of FIG. 11A), the second insulating capping pattern (138 of FIG. 11A), portions of the first insulating capping patterns (136 of FIG. 11A), and portions of the spacer structures (BLS of FIG. 11B) are etched back as shown in FIG. 13.

In this manner, a plurality of lower conductive patterns 158 may be exposed, while being apart from each other in the first horizontal direction (the X direction). Portions of the first insulating capping patterns (136 in FIG. 11A) may be etched back and changed into insulating capping patterns 136r with a reduced height. A first recessed opening 162 exposing the insulating capping pattern 136r may be formed between the plurality of lower conductive patterns 158. The lower conductive pattern 158 may be formed to protrude by a first vertical distance D1 from the first horizontal line PL1 on the upper surface of the insulating capping pattern 136r.

As shown in FIG. 14, portions of the fence insulating material layers (160 in FIG. 12) are etched back. In this manner, a plurality of lower conductive patterns 158 may be apart from each other and exposed in the second horizontal direction (the Y direction). The fence insulating material layer (160 in FIG. 12) may be etched back and changed into the fence insulating layer 160r with a reduced height. A second recessed opening 164 exposing the fence insulating layer 160r may be formed between the plurality of lower conductive patterns 158. The lower conductive pattern 158 may be formed to protrude by the first vertical distance D1 from the first horizontal line PL1 on the upper surface of the fence insulating layer 160r.

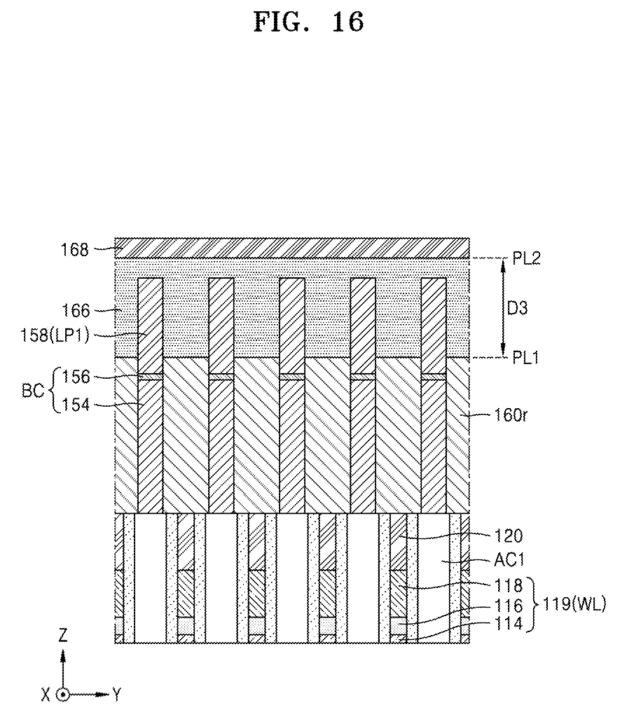

Referring to FIGS. 15 and 16, the landing insulating layer 166 is formed on the lower conductive pattern 158, while filling the first recessed opening hole (162 of FIG. 13) between the plurality of lower conductive patterns 158 apart from each other in the first horizontal direction (the X direction) as illustrated in FIG. 15. The landing insulating layer 166 may be formed by a third vertical distance D3 on the lower conductive pattern 158.

The stopper insulating layer 168 is formed on the landing insulating layer 166. An upper surface of the landing insulating layer 166 and a lower surface of the stopper insulating layer 168 may form the second horizontal line PL2. A vertical distance between the lower conductive pattern 158 and the second horizontal line PL2 may be a second vertical distance D2.

As illustrated in FIG. 16, the landing insulating layer 166 is formed on the lower conductive pattern 158, while filling the second recessed opening hole (164 in FIG. 14) between the plurality of lower conductive patterns 158 apart from each other in the second horizontal direction (the Y direction). The landing insulating layer 166 may be formed on the fence insulating layer 160r by the third vertical distance D3 The stopper insulating layer 168 is formed on the landing insulating layer 166. The upper surface of the landing insulating layer 166 and the lower surface of the stopper insulating layer 168 may form the second horizontal line PL2.

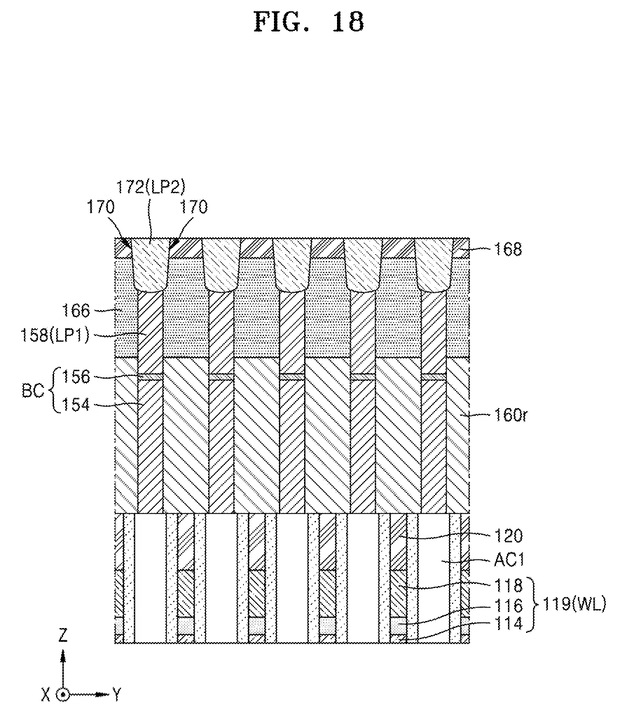

Referring to FIGS. 17 and 18, a plurality of landing opening holes 170 apart from each other in the horizontal direction (the X direction) are formed within the stopper insulating layer 168 and the landing insulating layer 166 as illustrated in FIG. 17. The landing opening hole 170 may be formed by patterning the landing insulating layer 166 and the stopper insulating layer 168 using a photolithography process. The landing opening 170 may be filled with a conductive material layer and then etched back to form the upper conductive patterns 172 apart from each other in the first horizontal direction (the X direction).

The upper conductive pattern 172 constitutes the second landing pad LP2. The second landing pad LP2 may be horizontally moved relative to the first landing pad LP1 in the first horizontal direction (the X direction) to be appropriately placed. A portion of the second landing pad LP2 may not vertically overlap the first landing pad LP1.

As shown in FIG. 18, a plurality of landing opening holes 170 apart from each other in the second horizontal direction (the Y direction) are formed within the stopper insulating layer 168 and the landing insulating layer 166. The landing opening hole 170 may be formed by patterning the landing insulating layer 166 and the stopper insulating layer 168 using a photolithography process. The landing opening 170 may be filled with a conductive material layer and then etched back to form a plurality of upper conductive patterns 172 apart from each other in the second horizontal direction (the Y direction).

The upper conductive pattern 172 constitutes the second landing pad LP2. The second landing pad LP2 may be positioned not to move horizontally in the second horizontal direction (the Y direction) relative to the first landing pad LP1. The second landing pad LP2 may vertically overlap the first landing pad LP1. One of more of the photolithography processes used to form patterns of the semiconductor device described in connection with FIGS. 11A to 18 may use a reticle and process such as described in connection with FIGS. 1A-5.

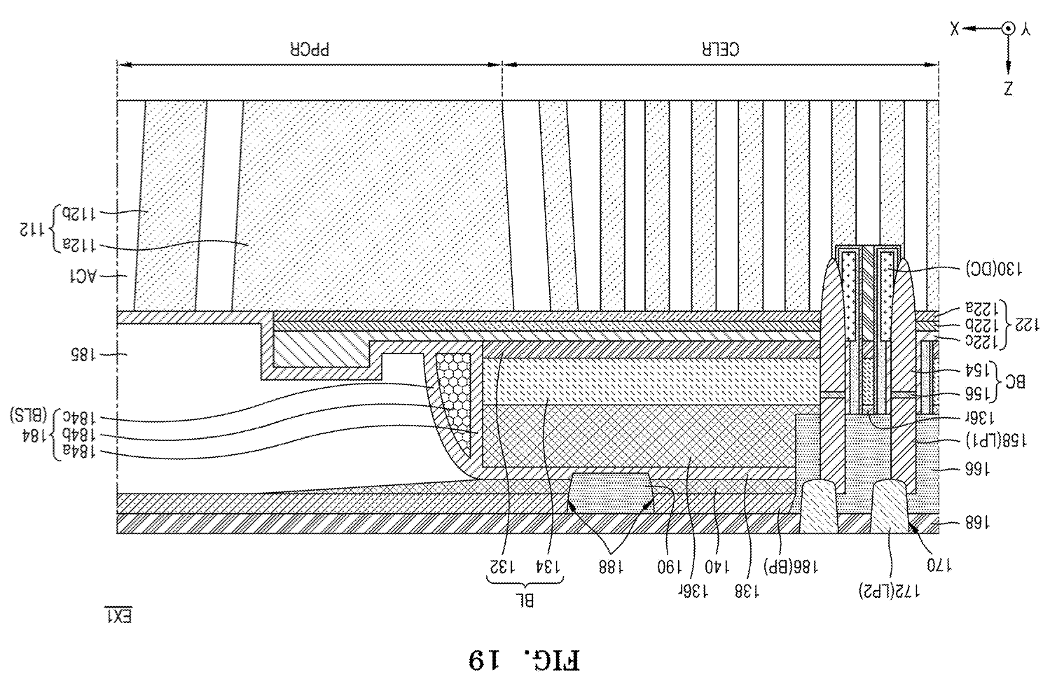

FIG. 19 is a cross-sectional view illustrating a cell region and a peripheral circuit region of a semiconductor device manufactured according to an embodiment.

In detail, FIG. 19 is a cross-sectional view illustrating the semiconductor device EX1 including the cell region CELR of FIG. 8A and the peripheral circuit region PPCR adjacent to the cell region CELR according to an embodiment. In FIG. 19, the description given above with reference to FIG. 8A is briefly given or omitted.

The semiconductor device EX1 may include the device isolation film 112 and the active regions AC1 (or active patterns) formed within the semiconductor substrate (110 of FIG. 8A). The device isolation film 112 may include the silicon oxide film 112a and the silicon nitride film 112b.

The buffer layer 122 formed in the cell region CELR may also be formed in the peripheral circuit region PPCR. The buffer layer 122 may include a first silicon oxide film 122a, a second silicon oxide film 122b, and a silicon nitride film 122c.

A plurality of bit lines BL apart from each other in the first horizontal direction (the X direction) are formed on the buffer layer 122. Bit lines BL may also be formed in the peripheral circuit region PPCR. The bit line BL may include the intermediate conductive pattern 132 and the upper conductive pattern 134. The spacer structure (BLS in FIG. 11B) may be formed on one side of the plurality of bit lines BL.

In the cell region CELR, the direct contact DC may be formed below the bit line BL and be connected to the active regions AC1 (or active patterns). The buried contact plug BC may be formed between the plurality of bit lines BL in the cell region CELR. The buried contact plug BC may include the plug conductive layer 154 and the plug metal silicide layer 156.

The first insulating capping pattern 136r is formed on the bit line BL in the cell region CELR. The second insulating capping pattern 138 and the third insulating capping pattern 140 may be formed on the first insulating capping pattern 136r. The second insulating capping pattern 138 and the third insulating capping pattern 140 may include a silicon nitride layer.

The peripheral circuit spacer structure (184, BLS) may be formed on one sidewall of the bit line BL, the first insulating capping pattern 136r, and the second insulating capping pattern 138. The peripheral circuit spacer structure 184 may include a silicon nitride film 184a, a silicon oxide film 184b, and a silicon nitride film 184c. The peripheral circuit interlayer insulating layer 185 may be formed in the peripheral circuit region PPCR. The peripheral circuit interlayer insulating layer 185 may include a silicon oxide layer.

A plurality of buried patterns BP may be formed on the third insulating capping pattern 140 and the peripheral circuit interlayer insulating layer 185. The buried pattern BP may include a conductive layer 186. The conductive layer 186 may include doped polysilicon, a metal, a metal silicide, a conductive metal nitride, or combinations thereof. In some embodiments, the conductive layer 186 may include tungsten (W).

The first landing pads LP1 apart from each other in the first horizontal direction (the X direction) may be formed on the buried contact plug BC of the cell region CELR. The first landing pad LP1 protrudes from the surface of the insulating capping pattern 136r above the bit line BL. The first landing pad LP1 may include the lower conductive pattern 158. An upper surface of the first landing pad LP1 may be nearly identical to an upper surface of the third insulating capping pattern 140.

The landing insulating layer 166 may be formed covering the upper portions of the plurality of first landing pads LP1, while surrounding the sidewalls of the first landing pads LP1 in the cell region CELR. An opening hole 188 may be formed within the conductive layer 186 using a photolithography process. In some embodiments, a lower surface of the opening hole 188 may be located on an upper surface of the second insulating capping pattern 138.

An insulating layer 190 is formed within the opening 188. The insulating layer 190 may include a silicon oxide layer. The landing insulating layer 166 and the insulating layer 190 of the cell region CELR may be formed during the same process.

The stopper insulating layer 168 is formed on the landing insulating layer 166 of the cell region CELR. The landing opening hole 170 is formed within the landing insulating layer 166 and the stopper insulating layer 168 in the cell region CELR. The second landing pad LP2 connected to the first landing pad LP1 is formed in the landing opening 170. The second landing pad LP2 may include the upper conductive pattern 172. One of more photolithography processes used to form patterns of the semiconductor device described in connection with FIG. 19 may use a reticle and process such as described in connection with FIGS. 1A-5.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming a mask layer on a pattern target layer;
exposing and developing the mask layer by using a multi-tone reticle including a white region and a gray region to form a first mask pattern region having a first thickness that exposes the pattern target layer and a second preliminary mask pattern region having a second sub-thickness that is less than the first thickness without exposing the pattern target layer;
etching the pattern target layer located below the first mask pattern region and the mask layer and the pattern target layer remaining below the second preliminary mask pattern region to form a first pattern in the pattern target layer having a first depth and a second pattern in the pattern target layer having a second depth that is less than the first depth; and
removing the mask layer.

2. The method of claim 1, wherein the gray region includes a plurality of slit line patterns and space patterns positioned between the plurality of slit line patterns.

3. The method of claim 1, wherein the white region includes an open window light-transmitting pattern.

4. The method of claim 1, wherein the white region is a region with a relatively larger amount of light transmittance that exposes the mask layer, and
the gray region is a region with a relatively smaller amount of light transmittance that exposes the mask layer than that of the white region.

5. The method of claim 4, wherein:
the amount of light transmittance of the white region is 100%, and
the amount of light transmittance of the gray region is between 25% and 75%.

6. The method of claim 1, wherein the forming of the first and second patterns includes:
further forming a second mask pattern region; and
etching the pattern target layer by using the first and second mask pattern regions as an etch mask to form the first and second patterns.

7. The method of claim 6, wherein the forming of the second mask pattern region, the first pattern, and the second pattern includes:
etching the pattern target layer located below the first mask pattern region to form a first preliminary pattern having a first sub-depth and further etching the mask layer remaining below the second preliminary mask pattern region to form a second mask pattern region having a second thickness that exposes the pattern target layer; and
further etching the pattern target layer located below the first mask pattern region and the first preliminary pattern to form the first pattern having the first depth and etching the pattern target layer located below the second mask pattern region to form the second pattern having the second depth that is less than the first depth.

8. The method of claim 7, wherein the first thickness is equal to the second thickness, and the first depth is deeper than the first sub-depth.

9. The method of claim 1, wherein the gray region is a first gray region, and the multi-tone reticle further includes at least a second gray region, wherein the method further comprises:
while exposing and developing the mask layer by using the multi-tone reticle to form the first mask pattern region having the first thickness that exposes the pattern target layer and the second preliminary mask pattern region having the second sub-thickness that is less than the first thickness without exposing the pattern target layer, forming a third preliminary mask pattern region having a third sub-thickness that is less than the second sub-thickness without exposing the pattern target layer, and
while etching the pattern target layer located below the first mask pattern region and the mask layer and the pattern target layer remaining below the second preliminary mask pattern region to form the first pattern in the pattern target layer having the first depth and the second pattern in the pattern target layer having the second depth that is less than the first depth, etching the mask layer and the pattern target layer located below the third preliminary mask pattern region to form a third pattern in the pattern target layer having a third depth that is less than the second depth.

10. The method of claim 9, wherein the first gray region of the multi-tone reticle is configured to allow a greater amount of light to pass therethrough than the second gray region of the multi-tone reticle.

11. A method of manufacturing a semiconductor device, the method comprising:
forming a mask layer on a pattern target layer;
exposing and developing the mask layer by using a multi-tone reticle including a white region and first to third gray regions to form a first mask pattern region having a first thickness that exposes the pattern target layer and second to fourth preliminary mask pattern regions respectively having second to fourth sub-thicknesses that are sequentially less than the first thickness, without exposing the pattern target layer;
etching the pattern target layer located below the first mask pattern region while etching the mask layer and the pattern target layer located below the second to fourth preliminary mask pattern regions to form first to fourth patterns respectively having first depth to fourth depth that are sequentially smaller; and
removing the mask layer.

12. The method of claim 11, wherein:
the first to third gray regions each include a plurality of first to third slit line patterns and first to third space patterns respectively positioned between the plurality of first to third slit line patterns,
widths of the plurality of second slit line patterns and the second space patterns are respectively less than widths of the plurality of first slit line patterns and the first space patterns, and
widths of the plurality of third slit line patterns and the third space patterns are respectively less than the widths of the plurality of second slit line patterns and the second space patterns.

13. The method of claim 11, wherein:
the white region includes an open window light-transmitting pattern,
the white region is a region with a relatively larger amount of light transmittance that exposes the mask layer, and
the first to third gray regions are regions with sequentially relatively smaller amounts of light transmittance that expose the mask layer than that of the white region,
wherein:
the amount of light transmittance of the first gray region is between 60% and 80%,
the amount of light transmittance of the second gray region is between 40% and 60%, and
the amount of light transmittance of the third gray region is between 20% and 40%..

14. The method of claim 11, wherein:
the first mask pattern region is formed to correspond to the white region, and
the second to fourth preliminary mask pattern regions are formed to correspond to the first to third gray regions, respectively.

15. The method of claim 11, wherein:
the forming of the first to fourth patterns includes:
further forming second, third, and fourth mask pattern regions; and
etching the pattern target layer by using the first to fourth mask pattern regions as an etch mask.

16. The method of claim 15, wherein the forming of the second, third, and fourth mask pattern regions includes:
etching the pattern target layer located below the first mask pattern region to form a first preliminary pattern and further etching the mask layer remaining below the second preliminary mask pattern region to form the second mask pattern region exposing the pattern target layer;
further etching the pattern target layer located below the first preliminary pattern, etching the pattern target layer located below the second mask pattern region to form a second preliminary pattern, and further etching the mask layer remaining below the third preliminary mask pattern region to form the third mask pattern region that exposes the pattern target layer, and
further etching the pattern target layer located below the first preliminary pattern and the second preliminary pattern, etching the pattern target layer located below the third mask pattern region to form a third preliminary pattern, and further etching the mask layer remaining below the fourth preliminary mask pattern region to form a fourth mask pattern region that exposes the pattern target layer.

17. The method of claim 16, wherein the forming of the first to fourth patterns includes:
further etching the pattern target layer located below the first mask pattern region and the first preliminary pattern to form the first pattern having the first depth;
further etching the pattern target layer located below the second mask pattern region and the second preliminary pattern to form the second pattern having the second depth that is less than the first depth;
further etching the pattern target layer located below the third mask pattern region and the third preliminary pattern to form the third pattern having the third depth less than the second depth, and
etching the pattern target layer located below the fourth mask pattern region to form the fourth pattern having the fourth depth that is less than the third depth.

18. A method of manufacturing a semiconductor device, the method comprising:
forming high-density mask patterns and low-density mask patterns separate from each other on a semiconductor substrate, wherein the semiconductor substrate is a pattern target layer, the high-density mask patterns are apart from each other, and the low-density mask patterns are apart from each other;
forming a mask layer on the high-density mask patterns and the low-density mask patterns;
exposing and developing the mask layer by using a multi-tone reticle including a white region and a gray region to form a first mask exposure pattern region exposing the semiconductor substrate and the low-density mask patterns and a second mask pattern region not exposing the semiconductor substrate or the high-density mask patterns;
etching the semiconductor substrate located below the first mask exposure pattern region to form first preliminary patterns and further etching the second mask pattern region to form a second mask exposure pattern region exposing the high-density mask patterns and the semiconductor substrate; and
further etching the semiconductor substrate located below the first mask exposure pattern region and the first preliminary patterns to form first patterns having a first depth and etching the semiconductor substrate located below the high-density mask patterns of the second mask exposure pattern region to form second patterns having a second depth that is less than the first depth,
wherein the first patterns are first trench patterns, the second patterns are second trench patterns, low-density active patterns are formed between the first trench patterns, and high-density active patterns are formed between the second trench patterns.

19. The method of claim 18, wherein
the high-density mask patterns are formed in a cell region of the semiconductor substrate, and
the low-density mask patterns are formed in a peripheral circuit region of the semiconductor substrate.

20. The method of claim 18, wherein the mask layer is removed at the time of forming the second mask exposure pattern region.
